(19) United States
(12) Patent Application Publication
(10) Pub. No.: US 2026/0190490 A1
(43) Pub. Date: Jul. 2, 2026

(54) DISPLAY SUBSTRATE AND DISPLAY APPARATUS

(71) Applicant: Tianma Advanced Display Technology Institute (Xiamen) Co., Ltd., Xiamen (CN)

(72) Inventors: Zhenyu JIA, Xiamen (CN); Jiali HUANG, Xiamen (CN); Kerui XI, Xiamen (CN); Tianyi WU, Xiamen (CN); Yingteng ZHAI, Xiamen (CN); Langbing LI, Xiamen (CN); Xiuli WANG, Xiamen (CN)

(73) Assignee: Tianma Advanced Display Technology Institute (Xiamen) Co., Ltd., Xiamen (CN)

(21) Appl. No.: 19/405,366

(22) Filed: Dec. 1, 2025

(30) Foreign Application Priority Data
Dec. 30, 2024 (CN) 202411977606.0

(51) Int. Cl. H10D 86/40; H10D 86/60

(52) U.S. Cl. CPC H10D 86/443; H10D 86/481; H10D 86/60

(57) ABSTRACT

The embodiments of the present application provide a display substrate and a display apparatus, comprising a first region and a second region, the first region is located at a side of the second region close to an edge of the display substrate; the second region comprising a plurality of first transistors; the display substrate comprising: a substrate; a lead wire located in the first region; conductive pads located between a film layer where the lead wire is located and the substrate; a first insulating layer located between a film layer where the conductive pad is located and the film layer where the lead trace is located, wherein in a direction perpendicular to a plane where the display substrate is located, the conductive pad and the lead trace overlap; and the first insulating layer is comprised between the conductive pad and the lead trace.

### CROSS-REFERENCE TO RELATED APPLICATIONS

The present application claims priority to Chinese Patent Application No. 202411977606.0, titled “DISPLAY SUBSTRATE AND DISPLAY APPARATUS” and filed on Dec. 30, 2024, which is hereby incorporated by reference in its entirety.

### TECHNICAL FIELD

The present application relates to the field of display technology, and in particular to a display substrate and a display apparatus.

### BACKGROUND

Electrostatic protection is one of the main research topics in the display field. Static electricity may damage devices in the display screen and affect the display performance of the display apparatus. With the development of display technology, narrow border display and ultra-narrow border display are gradually becoming mainstream displays. However, in narrow-border display substrates and ultra-narrow-border display substrates, static electricity is more likely to enter the interior of the display substrate and damage the devices. As the borders of display substrates become increasingly narrow, existing electrostatic protection structures face challenges.

Therefore, how to obtain a reliable electrostatic protection structure on a display substrate is a technical problem that needs to be solved urgently.

### SUMMARY

In a first aspect, some embodiments of the present application provide a display substrate comprising a first region and a second region, the first region being located at a side of the second region close to an edge of the display substrate; the second region comprising a plurality of first transistors, at least one of the first transistors being electrically connected to a first electrode; the display substrate comprising: a substrate; lead traces located in the first region; conductive pads located between a film layer where the lead traces are located and the substrate; a first insulating layer located between a film layer where the conductive pad is located and the film layer where the lead trace is located, wherein in a direction perpendicular to a plane where the display substrate is located, at least one of the conductive pads overlaps a corresponding one of the lead traces the first insulating layer being comprised between the conductive pads and the lead traces.

In a second aspect, some embodiments of the present application provide a display apparatus comprising the display substrate provided in the first aspect.

### BRIEF DESCRIPTION OF THE DRAWINGS

To more clearly illustrate the technical solutions of the embodiments of the present application, the drawings required for use in the embodiments are described briefly below, apparently, the drawings described below are only some embodiments of the present application. For those skilled in the art, other drawings can be obtained based on these drawings without any creative work.

FIG. 1 is a schematic diagram of a display substrate provided in some embodiments of the present application;

FIG. 2 is a schematic diagram of another display substrate provided in some embodiments of the present application;

FIG. 3 is a detailed schematic diagram of a partial region shown in FIGS. 1 and 2;

FIG. 4 is a schematic cross-sectional view in a direction of A1-A2 in FIG. 3;

FIG. 5 is a schematic diagram of a display substrate provided in some embodiments of the present application;

FIG. 6 is a schematic diagram of another display substrate provided in some embodiments of the present application;

FIG. 7 is a schematic cross-sectional view of a partial region of a display substrate provided in some embodiments of the present application;

FIG. 8 is a schematic cross-sectional view of a partial region of a display substrate provided in some embodiments of the present application;

FIG. 9 is a schematic cross-sectional view of a partial region of a display substrate provided in some embodiments of the present application;

FIG. 10 is a schematic cross-sectional view of a partial region of a display substrate provided in some embodiments of the present application;

FIG. 11 is a schematic cross-sectional view of a partial region of a display substrate provided in some embodiments of the present application;

FIG. 12 is a schematic cross-sectional view of a partial region of a display substrate provided in some embodiments of the present application;

FIG. 13 is a schematic cross-sectional view of a partial region of a display substrate provided in some embodiments of the present application;

FIG. 14 is a schematic cross-sectional view of a partial region of a display substrate provided in some embodiments of the present application;

FIG. 15 is a schematic cross-sectional view of a partial region of a display substrate provided in some embodiments of the present application;

FIG. 16 is a schematic cross-sectional view of a partial region of a display substrate provided in some embodiments of the present application;

FIG. 17 is a schematic cross-sectional view of a partial region of a display substrate provided in some embodiments of the present application;

FIG. 18 is a schematic cross-sectional view of a partial region of a display substrate provided in some embodiments of the present application;

FIG. 19 is a schematic cross-sectional view of a partial region of a display substrate provided in some embodiments of the present application;

FIG. 20 is a schematic cross-sectional view of a partial region of a display substrate provided in some embodiments of the present application;

FIG. 21 is a schematic cross-sectional view of a partial region of a display substrate provided in some embodiments of the present application;

FIG. 22 is a schematic cross-sectional view of a partial region of a display substrate provided in some embodiments of the present application;

FIG. 23 is a schematic cross-sectional view of a partial region of a display substrate provided in some embodiments of the present application;

FIG. 24 is a schematic cross-sectional view of a partial region of a display substrate provided in some embodiments of the present application;

FIG. 25 is a schematic cross-sectional view of a partial region of a display substrate provided in some embodiments of the present application;

FIG. 26 is a schematic cross-sectional view of a partial region of a display substrate provided in some embodiments of the present application;

FIG. 27 is a schematic cross-sectional view in a direction of B1-B2 in FIG. 3;

FIG. 28 is a detailed schematic diagram of a partial region in FIGS. 1 and 2;

FIG. 29 is a schematic cross-sectional view in a direction of C1-C2 in FIG. 28;

FIG. 30 is a schematic cross-sectional view in a direction of C1-C2 in FIG. 28;

FIG. 31 is a detailed schematic diagram of a partial region in FIGS. 1 and 2;

FIG. 32 is a detailed schematic diagram of a partial region in FIGS. 1 and 2;

FIG. 33 is a detailed schematic diagram of a partial region in FIGS. 1 and 2;

FIG. 34 is a detailed schematic diagram of a partial region in FIGS. 1 and 2;

FIG. 35 is a detailed schematic diagram of a partial region in FIGS. 1 and 2;

FIG. 36 is a detailed schematic diagram of a partial region in FIGS. 1 and 2;

FIG. 37 is a detailed schematic diagram of a partial region in FIGS. 1 and 2;

FIG. 38 is a detailed schematic diagram of a partial region in FIGS. 1 and 2;

FIG. 39 is a detailed schematic diagram of a partial region in FIGS. 1 and 2;

FIG. 40 is a detailed schematic diagram of a partial region in FIGS. 1 and 2;

FIG. 41 is a detailed schematic diagram of a partial region in FIGS. 1 and 2;

FIG. 42 is a detailed schematic diagram of a partial region in FIGS. 1 and 2;

FIG. 43 is a schematic cross-sectional view of a partial region of a display substrate provided in some embodiments of the present application;

FIG. 44 is a detailed schematic diagram of a partial region in FIGS. 1 and 2;

FIG. 45 is a detailed schematic diagram of a partial region in FIGS. 1 and 2;

FIG. 46 is a detailed schematic diagram of a partial region in FIGS. 1 and 2;

FIG. 47 is a detailed schematic diagram of a partial region in FIGS. 1 and 2;

FIG. 48 is a detailed schematic diagram of a partial region in FIGS. 1 and 2;

FIG. 49 is a detailed schematic diagram of a partial region in FIGS. 1 and 2;

FIG. 50 is a detailed schematic diagram of a partial region in FIGS. 1 and 2;

FIG. 51 is an overlap schematic diagram of lead traces and conductive pads in a display substrate provided in some embodiments of the present application;

FIG. 52 is a partial schematic diagram of a display substrate provided in some embodiments of the present application;

FIG. 53 is a partial schematic diagram of a display substrate provided in some embodiments of the present application;

FIG. 54 is partial schematic diagram of a display substrate provided in some embodiments of the present application;

FIG. 55 is partial schematic diagram of a display substrate provided in some embodiments of the present application;

FIG. 56 is a schematic cross-sectional view in a direction of D1-D2 in FIG. 54;

FIG. 57 is a schematic cross-sectional view in a direction of F1-F2 in FIG. 55;

FIG. 58 is another schematic cross-sectional view in a direction of D1-D2 in FIG. 54;

FIG. 59 is another schematic cross-sectional view in a direction of F1-F2 in FIG. 55;

FIG. 60 is another schematic cross-sectional view in a direction of D1-D2 in FIG. 54;

FIG. 61 is another schematic cross-sectional view in a direction of F1-F2 in FIG. 55;

FIG. 62 is a partial schematic diagram of a display substrate provided in some embodiments of the present application;

FIG. 63 is a partial schematic diagram of a display substrate provided in some embodiments of the present application;

FIG. 64 is a partial schematic diagram of a display substrate provided in some embodiments of the present application;

FIG. 65 is a schematic diagram of a display apparatus provided in some embodiments of the present application; and

FIG. 66 is a schematic diagram of a display apparatus provided in some embodiments of the present application.

### DETAILED DESCRIPTION

To better understand the technical solutions of the present application, the embodiments of the present application are described in detail below with reference to the drawings.

It should be understood that the embodiments described are only some of the embodiments of the present application, and not all of them. Based on the embodiments of the present application, all other embodiments derived by those skilled in the art without inventive effort are within the scope of protection of the present application.

The terms used in the embodiments of the present application are intended solely to describe specific embodiments and are not intended to limit the present application. The singular forms “a,” “an,” and “the” used in the embodiments and the appended claims of the present application are intended to include the plural forms, unless the context clearly indicates otherwise.

It should be understood that the term “and/or” as used herein is merely a description of an association relationship between related objects, indicating that three relationships exist. For example, “A and/or B” can represent: A exists alone, A and B exist simultaneously, or B exists alone. Furthermore, the character “/” in the present application generally indicates that the related objects are in an “or” relationship.

In the description of the present specification, it is necessary to understand that the terms “substantially”, “nearly”, “approximately”, “about”, “roughly”, “generally”, etc. described in the claims and embodiments of the present application refer to what can be generally recognized within a reasonable process operation range or tolerance range, rather than an exact value.

It should be understood that although the terms first, second, etc. may be used to describe regions, directions, lead traces, etc. in the embodiments of the present application, these should not be limited to these terms. These terms are only used to distinguish regions, directions, lead traces, etc. from each other. For example, without departing from the scope of the embodiments of the present application, the first region may also be referred to as the second region, and similarly, the second region may also be referred to as the first region. The applicant of the present application has provided a solution to the problems existing in the prior art through careful and in-depth research.

The display substrate provided in the embodiments of the present application is configured in display apparatus and can serve as a substrate for controlling pixel light emission in display apparatus.

The display substrate may include the light-emitting elements in the pixels. For example, the display substrate may include organic light-emitting diodes (OLEDs). The display substrate may also be coupled to the light-emitting elements in the pixels by plugging, welding, or bonding. For example, the display substrate may be coupled to light-emitting elements such as sub-millimeter light-emitting diodes (Mini-LEDs) and micro-light-emitting diodes (Micro-LEDs). Furthermore, the display substrate may also be configured in display apparatus such as liquid crystal displays (LCDs) and electrophoretic displays (EPDs) that achieve display by manipulating the optical path of light. In this case, the display substrate may be able to separately control the optical path of light in different pixels, which is not limited in the present application.

To control the light emission of pixels in a display apparatus, the display substrate includes a pixel circuit or a pixel control transistor. The pixel circuit or pixel control transistor is electrically connected to a first electrode and outputs a light-emitting control signal to the corresponding pixel through the first electrode. For example, when the display substrate includes an organic light-emitting diode (OLED), the first electrode can be the anode of the OLED. Furthermore, the display substrate further includes a second electrode, which can be the cathode of the OLED. When the display substrate is combined with a Mini-LED or Micro-LED, the first electrode can be an electrode electrically connected to the anode of the Mini-LED/Micro-LED. When the display substrate is configured in a display apparatus such as an LCD or EPD, the first electrode can be a pixel electrode. The first electrode is an electrode configured for light-emitting control.

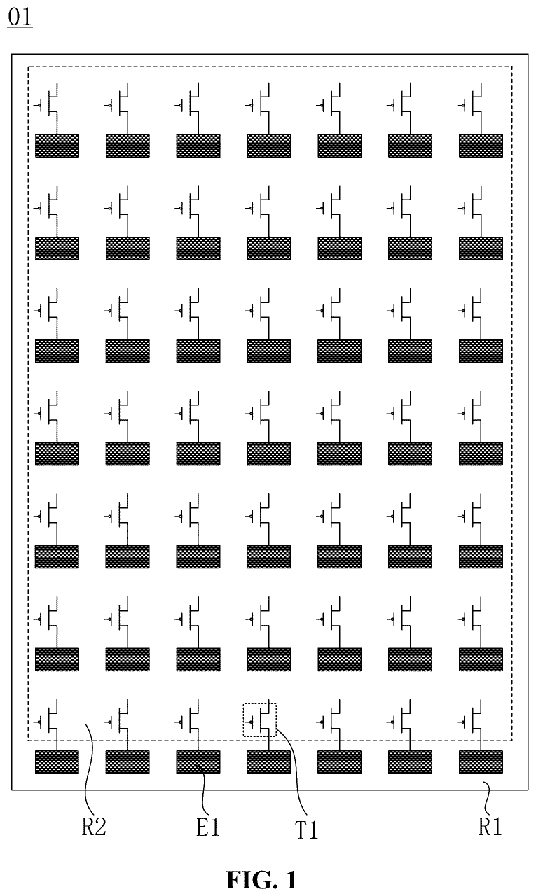

FIG. 1 is a schematic diagram of a display substrate provided in some embodiments of the present application, and FIG. 2 is a schematic diagram of another display substrate provided in some embodiments of the present application.

As shown in FIGS. 1 and 2, the display substrate 01 includes a first region R1 and a second region R2. The first region R1 is located on the side of the second region R2 close to the edge of the display substrate 01. The display substrate 01 can be a narrow-border display substrate 01. In this case, the first region R1 is the border region where peripheral circuits and peripheral traces are disposed, while the second region R2 is the display area for light-emitting display. In this case, the first electrode E1 can be located in the second region R2 and not in the first region R1. The display substrate 01 can also be a borderless display substrate 01 or an ultra-narrow border display substrate 01. Both the first region R1 and the second region R2 are regions for light-emitting display, and the first region R1 is closer to the edge of the display substrate 01 than the second region R2. In this case, the first region R1 and the second region R2 each can include a first electrode E1.

The second region R2 includes multiple first transistors T1, the first transistor T1 is electrically connected to the first electrode E1. Whether the first electrode E1 receives a signal to control pixel light emission can depend on the state of the first transistor T1. When the first electrode E1 is electrically connected to the pixel circuit, the first transistor T1 can be a transistor directly electrically connected to the first electrode E1 in the pixel circuit; when the first electrode E1 is electrically connected to the pixel control transistor, the first electrode E1 can be the pixel control transistor. It should be noted that the first transistor T1 being electrically connected to the first electrode E1 can mean that the first transistor T1 is directly connected to the first electrode E1 via a conductive structure, rather than requiring the first transistor T1 to be electrically connected to the first electrode E1 through a control structure.

In some embodiments, as shown in FIG. 1, the first transistor T1 is electrically connected to the first electrode E1 of the second region R2. In these embodiments, the first region R1 of the display substrate 01 does not include the first electrode E1, while the second region R2 includes the first electrode E1.

In some embodiments, as shown in FIG. 2, the first transistor T1 is electrically connected to the first electrodes E1 of both the first region R1 and the second region R2. In these embodiments, each of the first region R1 and the second region R2 of the display substrate 01 includes the first electrode E1.

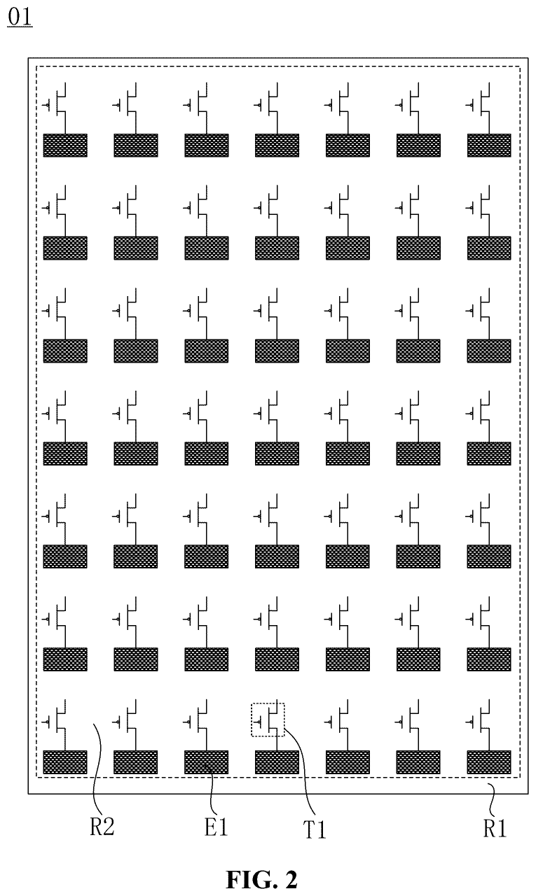

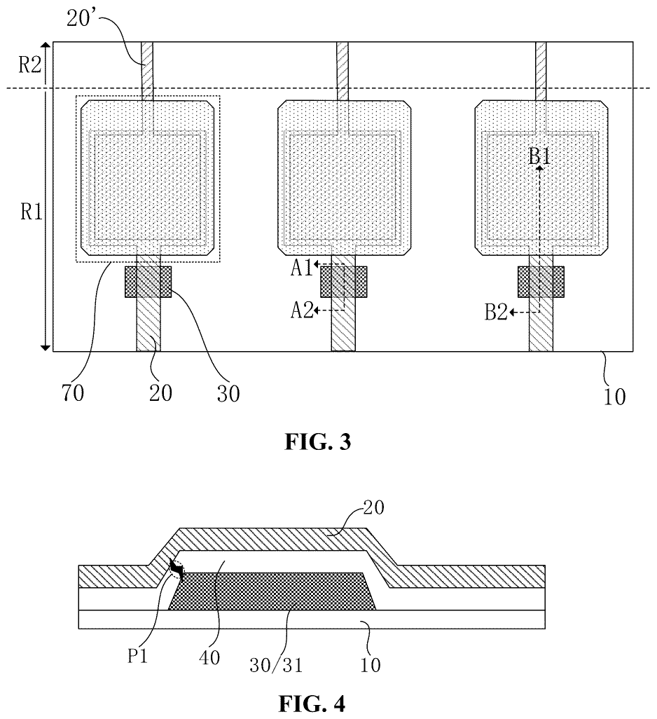

FIG. 3 is a detailed schematic diagram of a partial region shown in FIGS. 1 and 2, and FIG. 4 is a schematic cross-sectional view in a direction of A1-A2 in FIG. 3.

In the embodiments of the present application, referring to FIGS. 3 and 4, the display substrate 01 includes a substrate 10, a lead trace 20, a conductive pad 30, and a first insulating layer 40. As shown in FIG. 4, the lead trace 20 is located on one side of the substrate 10, and the conductive pad 30 is located between the film layer where the lead trace 20 is located and the substrate 10. Therefore, when manufacturing the display substrate 01, the lead trace 20 is obtained by manufacturing after the conductive pad 30 is completed by manufacturing. The first insulating layer 40 is located between the film layer where the conductive pad 30 is located and the film layer where the lead trace 20 is located. Therefore, when manufacturing the display substrate 01, the first insulating layer 40 is obtained by manufacturing after the conductive pad 30 is manufactured and before the first insulating layer 40 is manufactured.

The lead traces 20 are located in the first region R1, that is, the lead traces 20 are located in a region close to the edge of the display substrate 01. The lead traces 20 can be electrically connected to at least parts of functional signal lines 20′, such as data lines, power lines, reset lines, and clock lines. The lead traces 20 can also be configured to electrically connect to an external test fixture. Therefore, at least parts of these functional signal lines 20′ can be electrically connected to an external test fixture, thereby achieving performance testing of the display substrate 01. The overall extension direction of the lead traces 20 can be substantially parallel to the arrangement direction of the first region R1 and the second region R2 where the lead traces 20 are located.

Referring to FIG. 4, since the first insulating layer 40 is formed after the conductive pad 30, when the first insulating layer 40 is obtained by manufacturing, the first insulating layer 40 exhibits a ramping phenomenon at the sidewall position of the conductive pad 30, which results in a change in a structural characteristic of the first insulating layer 40, including a reduction in thickness of a portion where the first insulating layer 40 is at the position close to the sidewall and the sidewall position of the conductive pad 30. For example, as shown in FIG. 4, a thickness of a portion where the first insulating layer 40 is at the sidewall of the conductive pad 30 is reduced, a thickness of a portion where the first insulating layer 40 is at a position close to an edge of a top surface of the conductive pad 30 is also reduced. A place where the thickness of the first insulating layer 40 is reduced at the position close to the sidewall and the sidewall position of the conductive pad 30 is called a weak point P1.

As shown in FIG. 3, in a direction perpendicular to the plane where the display substrate 01 is located, the conductive pad 30 overlaps the lead trace 20. A first insulating layer 40 is included between the conductive pad 30 and the lead trace 20. Therefore, at least parts of the weak points P1 of the first insulating layer 40 are also located between the conductive pad 30 and the lead trace 20, wherein both the conductive pad 30 and the lead trace 20 are electrically conductive.

When static electricity is present at the edge of the display substrate 01, the static electricity can enter the lead trace 20. For example, when the edge of the display substrate 01 is grinded, at least some of the static electricity generated by the grinding can enter the lead trace 20. Since there is a weak point P1 in the first insulating layer 40 between the lead trace 20 and the conductive pad 30, static electricity can easily break through the weak point P1 in the first insulating layer 40 when forming a path in the lead trace 20, thereby releasing static electricity.

In the embodiments of the present application, in order to allow the lead trace 20 to overlap the weak point P1 of the first insulating layer 40 so that static electricity in the lead trace 20 can break through the weak point P1, the lead trace 20 should overlap at least parts of the sidewalls of the conductive pad 30 in a direction perpendicular to the display substrate 01. For example, as shown in FIG. 3, the lead trace 20 extends along the column direction and partially overlaps the upper and lower sidewalls of the conductive pad 30.

The first region R1 may at least partially surround the second region R2. For example, as shown in FIGS. 1 and 2, the first region R1 surrounds the second region R2. The arrangement direction of the second region R2 with a part of the first region R1 is different from the arrangement direction of the second region R2 with another part of R1. For example, as shown in FIGS. 1 and 2, the arrangement direction of the second region R2 with the left and right sides of the first region R1 is parallel to the row direction, and the arrangement direction of the second region R2 with the upper and lower sides of the first regions R1 is parallel to the column direction.

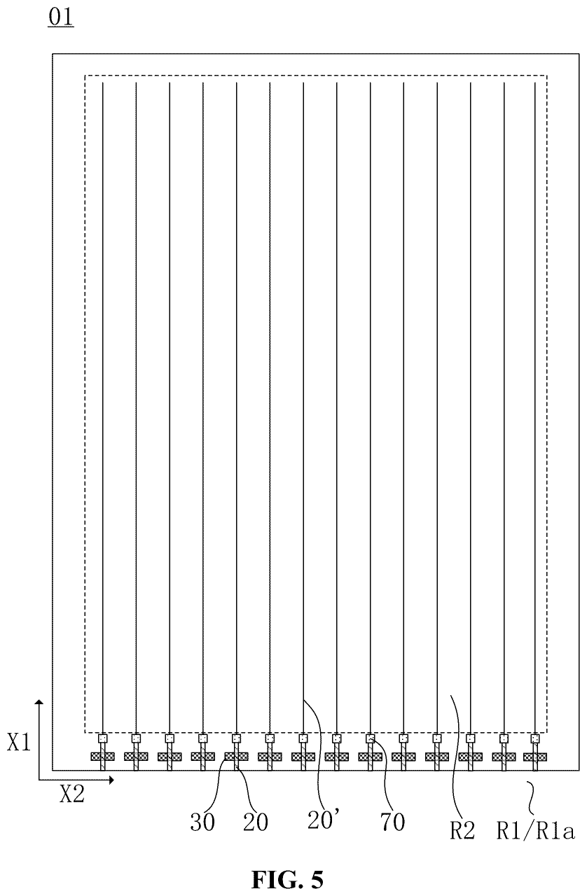

FIG. 5 is a schematic diagram of a display substrate provided in some embodiments of the present application.

In some embodiments of the present application, as shown in FIG. 5, the lead traces 20 and conductive pads 30 that overlap in a direction perpendicular to the plane where the display substrate 01 is located are located in a first-type first region R1a. The first-type first region R1a is a region within the first region that is arranged along the first arrangement direction X1 with the second region R2. Specifically, the lead traces 20 and conductive pads 30 that are overlapped with each other are concentrated in the first region R1 on the same side of the second region R2.

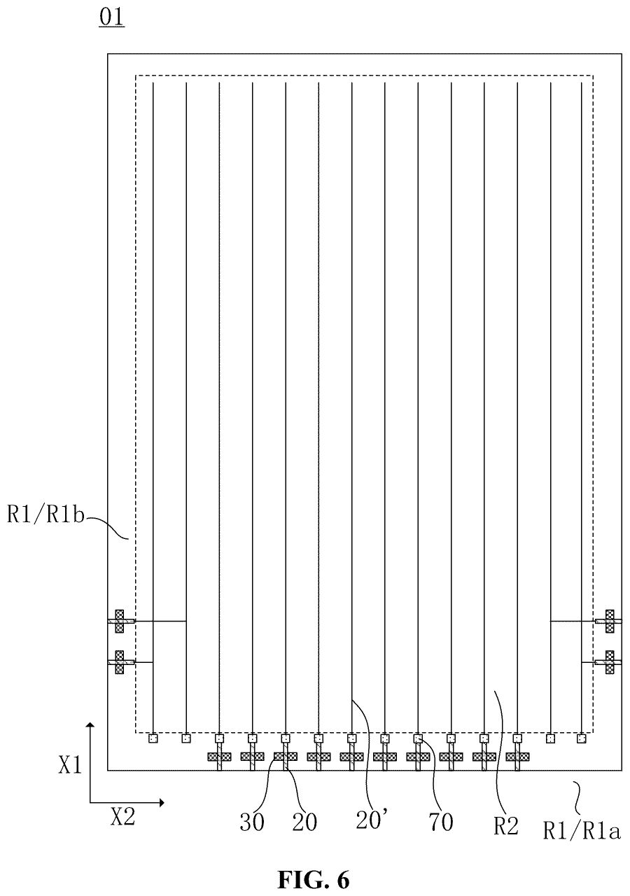

FIG. 6 is a schematic diagram of another display substrate provided in some embodiments of the present application.

In some embodiments of the present application, as shown in FIG. 6, the first region R1 includes a first-type first region R1a and a second-type first region R1b. Along the first arrangement direction X1, the first-type first region R1a is located on one side of the second region R2; along the second arrangement direction X2, the second-type first region R1 is located on one side of the second region R2, with the first arrangement direction X1 and the second arrangement direction X2 intersecting. For example, the first-type first region R1a and the second region R2 are arranged along the first arrangement direction X1 and below the second region R2, while the second-type second region R1b and the second region R2 are arranged along the second direction X2 and at the left and right sides of the second region R2.

In this embodiment, each of the first-type first region R1a and the second-type first region R1b includes lead traces 20 and conductive pads 30. Specifically, the lead traces 20 and conductive pads 30 that are overlapped with each other are distributed in the first regions R1 at different sides of the second region R2.

Distributing the lead traces 20 in the first regions R1 at different sides of the second region R2 can reduce the difficulty of wiring the lead traces 20. The density of the lead traces 20 within a first region R2 can also be reduced, thereby reducing the difficulty of electrically connecting the lead traces 20 to the external test fixture and improving the accuracy of the electrical connecting the lead traces 20 to the external test fixture. In this embodiment, the conductive pads 30 are also distributed in the different first regions R1 where the lead traces 20 are located. Therefore, the lead traces 20 distributed in the first regions R1 at different sides of the second region R2 each have a corresponding weak point P1 for electrostatic discharge.

It should be noted that the technical solutions provided in the following embodiments are applicable to situations where the lead traces 20 and conductive pads 30 that are overlapped with each other are located only in the first-type first region R1a, as well as situations where each of the first-type first region R1a and the second-type first region R1b includes lead traces 20 and conductive pads 30 are overlapped with each other.

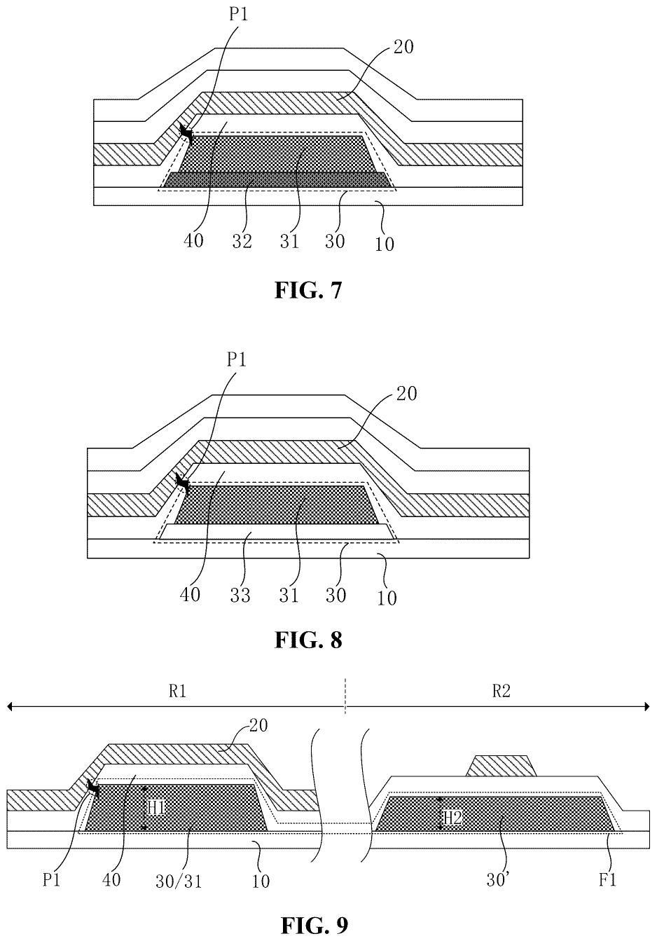

FIG. 7 is a schematic cross-sectional view of a partial region of a display substrate provided in some embodiments of the present application, and FIG. 8 is a schematic cross-sectional view of a partial region of a display substrate provided in some embodiments of the present application. In FIG. 7 and FIG. 8, the structures filled with patterns are conductor or semiconductor structures, and the structures filled with white are insulating structures.

In some embodiments of the present application, as shown in FIGS. 7 and 8, the conductive pad 30 includes at least two portions stacked in a direction perpendicular to the plane where the display substrate 01 is located. On the one hand, the conductive pad 30 can be allowed to have a larger thickness as a whole; on the other hand, at least two stacked portions in the conductive pad 30 can be etched separately. Therefore, the process of manufacturing each portion with a large sidewall inclination angle is less difficult, and it is easy to make the sidewall of the conductive pad 30 have a larger inclination angle.

In a technical solution corresponding to these embodiments, as shown in FIG. 7, the conductive pad 30 comprises a first portion 31 and a second portion 32 stacked in a direction perpendicular to the plane where the display substrate 01 is located. The first portion 31 is a conductor or semiconductor, and the second portion 32 is also a conductor or semiconductor. In one implementation, the first portion 31 and the second portion 32 can be electrically connected to increase the likelihood of discharge from the lead trace 20 to the conductive pad 30.

In one technical solution corresponding to these embodiments, as shown in FIG. 8, the conductive pad 30 includes a first portion 31 and a third portion 33 stacked in a direction perpendicular to the plane where the display substrate 01 is located. The first portion 31 is a conductor or semiconductor, and the third portion 33 is an insulator. The first portion 31 is located on the side of the third portion 33 close to the first insulating layer 40. Therefore, the first portion 31 serving as a conductor or semiconductor is closer to the first insulating layer 40, and electrical conduction is more easily formed between the first portion 31 and the first insulating layer 40 at the weak point P1.

The semiconductor portion of the conductive pad 30 can be a heavily doped semiconductor. It should be noted that when the conductive pad 30 includes only the semiconductor portion in addition to the insulating portion, the semiconductor portion can be heavily doped to ensure a certain degree of conductivity.

It should be noted that the conductive pad 30 can include two portions stacked in a direction perpendicular to the plane where the display substrate 01 is located, or three or more portions.

In some embodiments of the present application, as shown in FIG. 4, the conductive pad 30 may also include only the first portion 31, which reduces the difficulty of manufacturing the conductive pad 30.

It should be noted that the following embodiments and drawings are mainly described using the example that the conductive pad 30 only includes the first portion 31, but the following embodiments are also applicable to the case where the conductive pad 30 includes the first portion 31 and the second portion 32, and the conductive pad 30 includes the first portion 31 and the third portion 33.

FIG. 9 is a schematic cross-sectional view of a partial region of a display substrate provided in some embodiments of the present application.

As shown in FIG. 9, the display substrate 01 includes a first film layer F1, which includes a first structure 30′ in the second region R2. The conductive pad 30 includes at least the first portion 31, and the first portion 31 is located in the first film layer F1. Therefore, the first film layer F1 of the display substrate 01 includes the first portion 31 located in the first region R1 and the first structure 30′ located in the second region R2.

In some embodiments of the present application, as shown in FIG. 9, the thickness H1 of the first portion 31 in a direction perpendicular to the plane where the display substrate 01 is located is greater than the thickness H2 of the first structure 30′ in a direction perpendicular to the plane where the display substrate 01 is located. It should be noted that the thickness H1 of the first portion 31 refers to the thickness of the portion thereof on the relatively flat supporting surface parallel to the substrate 10 in a direction perpendicular to the plane where the display substrate 01 is located; the thickness H2 of the first structure 30′ refers to the thickness of the portion thereof on the relatively flat supporting surface parallel to the substrate 10 in a direction perpendicular to the plane where the display substrate 01 is located.

In these embodiments, the thickness of the first film layer F1 in a direction perpendicular to the plane where the display substrate 01 is located is designed differently, and the thickness H1 of the first portion 31 belonging to the conductive pad 30 is relatively greater. When the thickness H1 of the first portion 31 of the conductive pad 30 is relatively greater, it is conductive to achieving a greater thickness of the conductive pad 30 in a direction perpendicular to the plane where the display substrate 01 is located, and is more conducive to the first insulating layer 40 forming a weak point P1 at the position close to the sidewall and the sidewall position of the conductive pad 30, and the thickness of the first insulating layer 40 at the weak point P1 can be further reduced. Therefore, when the thickness H1 of the first portion 31 of the first film layer F1 is greater than the thickness H2 of the first structure 30′ in the first film layer F1, it is more conducive to the discharge of static electricity at the edge position of the display substrate 01 at a position of the conductive pad 30 and a position close to the conductive pad 30, further reducing the impact of static electricity at the edge of the display substrate 01 on other functional structures of the display substrate 01 including functional signal lines, so that the display substrate 01 has a good display effect.

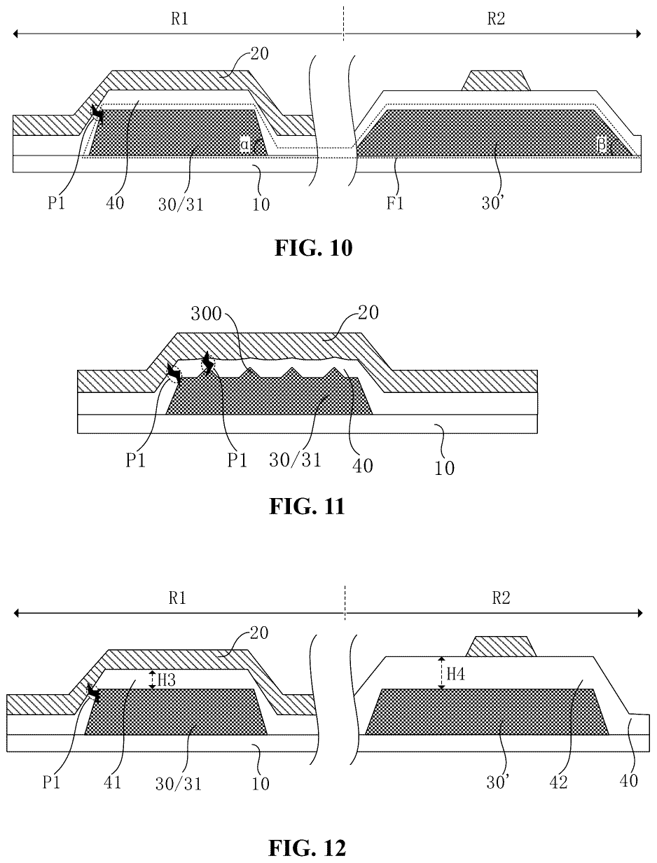

FIG. 10 is a schematic cross-sectional view of a partial region of a display substrate provided in some embodiments of the present application.

In some embodiments of the present application, as shown in FIG. 10, the sidewall inclination angle of the first portion 31 is greater than the sidewall inclination angle of the first structure 30′. The sidewall inclination angle refers to the angle between the sidewall and the plane where the substrate 10 is located. As shown in FIG. 10, the sidewall inclination angle of the first portion 31 is α, and the sidewall inclination angle of the first structure 30′ is β, where α>β. The sidewall inclination angle of the first portion 31 is greater than that of the first structure 30′, that is, the sidewall of the first portion 31 is more perpendicular to the sidewall of the first structure 30′.

In these embodiments, the sidewall inclination angles of the structures included in the first film layer F1 are designed differentially, and the sidewall inclination angle of the first portion 31 belonging to the conductive pad 30 is relatively greater. When the sidewall inclination angle of the first portion 31 is relatively greater, the thickness of the first insulating layer 40 attached to the sidewall of the first portion 31 is thinner, which is more conducive to the first insulating layer 40 forming a weak point P1 at the position close to the sidewall and the sidewall position of the conductive pad 30, and the thickness of the first insulating layer 40 at the weak point P1 can be further reduced. Therefore, when the sidewall inclination angle of the first portion 31 is greater than the sidewall inclination angle of the first structure 30′, it is more conducive to the discharge of static electricity at the edge position of the display substrate 01 at the position of conductive pad 30 and the position close to the conductive pad 30, further reducing the impact of static electricity at the edge of the display substrate 01 on other functional structures in the display substrate 01 including functional signal lines, so that the display substrate 01 has a good display effect.

It should be noted that the inclination angle of the sidewall of the conductive pad 30 that overlaps the lead trace 20 affects the characteristics of the weak point P1. Therefore, the above-mentioned sidewall inclination angle and the following sidewall inclination angles refer to the inclination angle of the sidewall that overlaps the lead trace 20 in a direction perpendicular to the plane where the display substrate 01 is located.

FIG. 11 is a schematic cross-sectional view of a partial region of a display substrate provided in embodiments of the present application.

In some embodiments of the present application, as shown in FIG. 11, the surface of the conductive pad 30 facing away from the substrate 10 includes at least one protrusion 300. As can be understood, the conductive pad 30 is manufactured on one side of the substrate 10, and the protrusion 300 is located on the surface of the conductive pad 30 facing away from the substrate 10. Therefore, the at least one protrusion 300 included in the conductive pad 30 is a protrusion 300 facing away from the substrate 10. During the subsequent preparation of the first insulating layer 40, the thickness of the portion of the first insulating layer 40 overlapping the protrusion 300 is reduced, easily forming a weak point P1. Furthermore, in a direction perpendicular to the plane where the display substrate 01 is located, the lead trace 20 overlaps the protrusion 300 included in the conductive pad 30. Therefore, the lead trace 20 also overlaps the weak point P1 at the location of the protrusion 300, facilitating static discharge.

Furthermore, because the conductive pad 30 includes the protrusion 300, if some static electricity from the display substrate 01 accumulates on the conductive pad 30, the conductive pad 30 facilitates tip discharge, which is conducive to the discharge of some static electricity at the edge of the display substrate 01.

Optionally, the protrusion 300 included on the surface of the conductive pad 30 facing away from the substrate 10 may be a tip-shaped structure.

FIG. 12 is a schematic cross-sectional view of a partial region of a display substrate provided in some embodiments of the present application.

In some embodiments of the present application, as shown in FIG. 12, the thickness H of the portion of the first insulating layer 40 located between the conductive pad 30 and the lead trace 20 is less than the thickness H4 of the portion of the first insulating layer 40 located in the second region R2. Referring to FIG. 12, the first insulating layer 40 includes a first insulating portion 41 and a second insulating portion 42. The first insulating portion 41 is located between the conductive pad 30 and the lead trace 20, and the second insulating portion 42 is located in the second region R2. The thickness H3 of the first insulating portion 41 is less than the thickness H4 of the second insulating portion 42. It should be noted that the thickness H3 of the first insulating portion 41 refers to the thickness of the portion thereof on the relatively flat supporting surface parallel to the substrate 10 in a direction perpendicular to the plane where the display substrate 01 is located; the thickness H4 of the second insulating portion 42 refers to the thickness of the portion thereof on the relatively flat supporting surface parallel to the substrate 10 in a direction perpendicular to the plane where the display substrate 01 is located.

In these embodiments, the thickness of the first insulating layer 40 in the direction perpendicular to the plane where the display substrate 01 is located is designed differentially, and the thickness H3 of the first insulating portion 41 between the conductive pad 30 and the lead trace 20 is relatively smaller. When the thickness H3 of the first insulating portion 41 of the first insulating layer 40 is relatively smaller, it is more conducive to making the thickness of the first insulating layer 40 at the position close to the sidewall and the sidewall position of the conductive pad 30 thinner when manufacturing the first insulating layer 40, thereby obtaining a more ideal weak point P1, which is more conducive to forming the weak point P1 with an electrostatic discharge path.

In some embodiments of the present application, the first insulating layer 40 is an inorganic material film layer, that is, the first insulating layer 40 is a film layer made of an inorganic material. In the display substrate 01, the thickness of the inorganic material film layer is generally relatively thin, which can prevent excessive stress and cracking caused by a relatively thick inorganic material film layer, and the inorganic material film layer also has advantages such as ease of etching. The first insulating layer 40 is an inorganic material film layer within the display substrate 01, that is, the first insulating layer 40 is a relatively thin insulating layer in the display substrate 01. Therefore, the weak point P1 can be easily formed at the overlapping positions of the position close to the sidewall and the sidewall position of the conductive pad 30 with the first insulating layer 40.

It should be noted that whether or not there are protrusions, the components, thickness, sidewall inclination angle of the conductive pad 30 in the display substrate 01, thickness of the first insulating layer 40 and other solutions provided in the above embodiments of the present application are also applicable to the following embodiments.

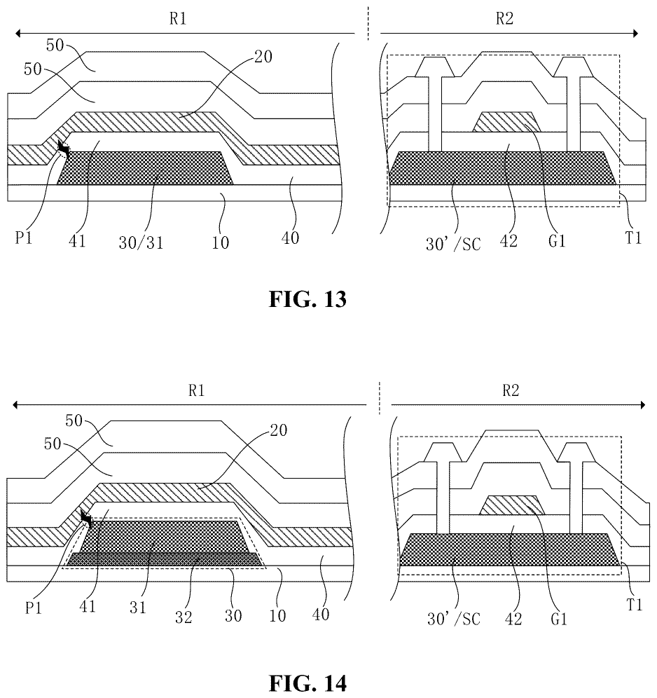

FIG. 13 is a schematic cross-sectional view of a partial region of a display substrate provided in some embodiments of the present application.

In some embodiments of the present application, as shown in FIG. 13, the first transistor T1 includes a semiconductor layer SC and a gate G1. A first insulating layer 40 is located between the semiconductor layer SC and the gate G1, which can be understood as meaning that the first insulating layer 40 includes a portion located in the first region R1 between the lead trace 20 and the conductive pad 30, and a portion located in the second region R2 and between the semiconductor layer SC and the gate G1 of the first transistor T1. That is, in these embodiments, the first insulating layer 40 includes a first insulating portion 41 and a second insulating portion 42. The first insulating portion 41 is located between the lead trace 20 and the conductive pad 30, and the second insulating portion 42 is located between the gate G1 and the semiconductor layer SC of the first transistor T1.

In these embodiments, at least a portion of the conductive pad 30 is located in the same film layer as the semiconductor layer SC, and at least a portion of the lead trace 20 is located in the same film layer as the gate G1. Therefore, at least a portion of the conductive pad 30 is manufactured simultaneously with the gate G1 of the first transistor T1, and at least a portion of the lead trace 20 is manufactured simultaneously with the semiconductor layer SC of the first transistor T1. For example, as shown in FIG. 13, the film layer where the semiconductor layer SC of the first transistor T1 is located includes a first portion 31 and a first structure 30′. The first portion 31 is the first portion 31 of the conductive pad 30, and the first structure 30′ is reused as the semiconductor layer SC of the transistor.

To ensure that the gate G1 of the transistor controls the channel of the semiconductor layer SC, generally, only one inorganic material film layer is included between the gate G1 and the semiconductor layer SC as an insulating layer and the thickness of the insulating layer is relatively thin. Therefore, in these embodiments, at least a portion of the conductive pad 30 is located in the same film layer as the semiconductor layer SC of the first transistor T1, the first insulating layer 40 is located in the same film layer as the insulating layer between the gate G1 and the semiconductor layer SC of the first transistor T1, and at least a portion of the lead trace 20 is located in the same film layer as the gate G1 of the first transistor T1. In this way, a weak point P1 for electrostatic discharge can be easily obtained between the lead trace 20 and the conductive pad 30 without increasing the difficulty of the process.

The semiconductor layer SC of the first transistor T1 includes a channel and source and drain regions. The source and drain regions are heavily doped. The portion of the conductive pad 30 located in the same film layer as the semiconductor layer SC can also be a heavily doped semiconductor structure. That is, the portion of the conductive pad 30 located in the same film layer as the semiconductor layer SC can also be manufactured using deposition, etching, doping, and other processes simultaneously with the source and drain regions of the semiconductor layer SC included in the first transistor T1.

FIG. 14 is a schematic cross-sectional view of a partial region of a display substrate provided in some embodiments of the present application.

In a technical solution corresponding to these embodiments, as shown in FIG. 14, the conductive pad 30 includes a first portion 31 and a second portion 32. The first portion 31 is a semiconductor and located in the same film layer as the semiconductor layer SC of the first transistor T1. The second portion 32 is a conductor and located between the first portion 31 and the substrate 10. In this technical solution, a conductive film layer is located between the film layer where the semiconductor layer SC of the first transistor T1 is located and the substrate 10, the film layer includes the second portion 32 of the conductive pad 30.

For example, if the second portion 32 is a metal structure or a metal composite structure, then the film layer where the semiconductor layer SC of the first transistor T1 is located and the substrate are provided therebetween with a metal film layer or a metal composite film layer, and the second portion 32 of the conductive pad 30 included in the metal film layer or the metal composite film layer.

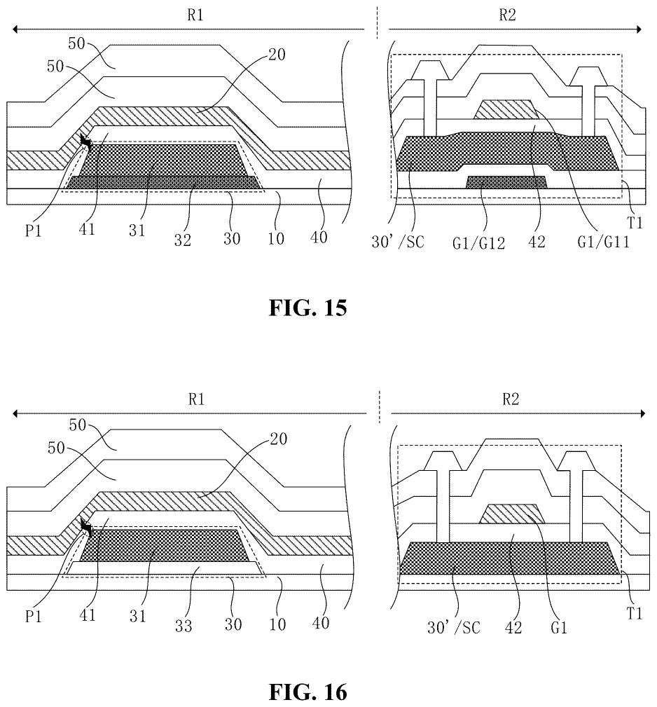

FIG. 15 is a schematic cross-sectional view of a partial region of a display substrate provided in some embodiments of the present application.

In one implementation, as shown in FIG. 15, the first transistor T1 can be a dual-gate transistor including top and bottom gates, that is, the first transistor T1 includes a top gate G11 located on the side of semiconductor layer SC away from the substrate 10, and a bottom gate G12 located on the side closer to the substrate 10. In this implementation, the lead trace 20 and the top gate G11 of the first transistor T1 are located in the same film layer, the first portion 31 of the conductive pad 30 and the semiconductor layer SC of the first transistor T1 are located in the same film layer, and the second portion 32 of the conductive pad 30 and the bottom gate G12 of the first transistor T1 are located in the same film layer.

FIG. 16 is a schematic cross-sectional view of a partial region of a display substrate provided in some embodiments of the present application.

In one technical solution corresponding to these embodiments, as shown in FIG. 16, the conductive pad 30 includes a first portion 31 and a third portion 33. The first portion 31 is a semiconductor and is located in the same film layer as the semiconductor layer SC of the first transistor T1. The third portion 33 is an insulator and is located between the first portion 31 and the substrate 10. In this technical solution, an insulating film layer is located between the film layer where the semiconductor layer SC of the first transistor T1 is located and the substrate 10, and this film layer includes the third portion 33 of the conductive pad 30.

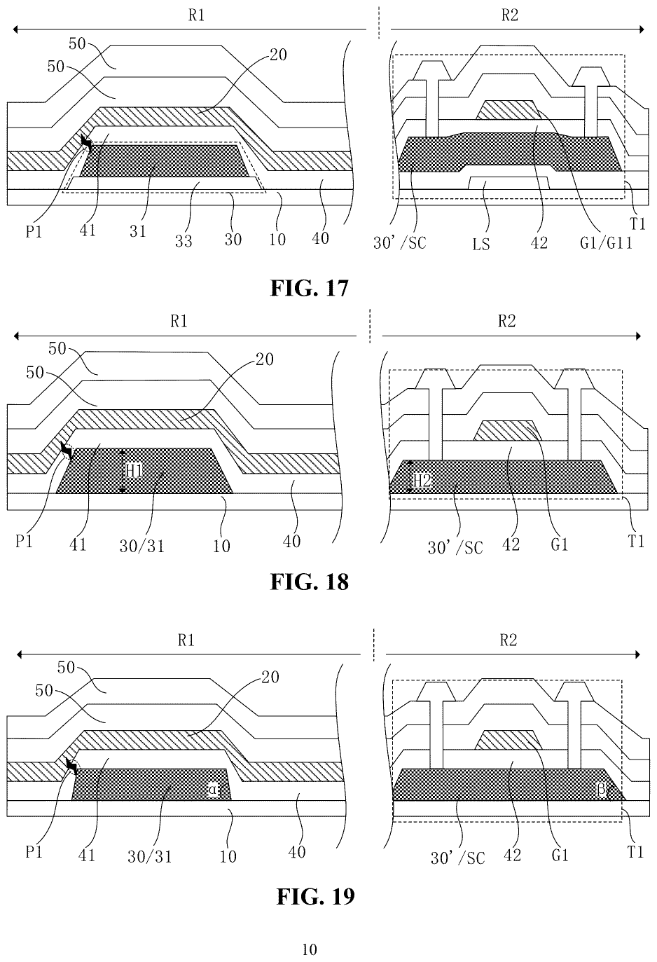

FIG. 17 is a schematic cross-sectional view of a partial region of a display substrate provided in some embodiments of the present application.

In one implementation, as shown in FIG. 17, the insulating layer between the film layer where the semiconductor layer SC of the first transistor T1 is located and the substrate 10 may include a buffer layer (not shown) and/or a light-shielding layer LS. The buffer layer between the semiconductor layer SC of the first transistor T1 and the substrate 10 prevents impurities in the substrate 10 from entering the semiconductor layer SC, which would otherwise affect the performance of the semiconductor layer SC. The light-shielding layer LS between the semiconductor layer SC of the first transistor T1 and the substrate 10 may overlap the channel of the semiconductor layer SC to prevent external light from irradiating on the semiconductor layer SC, which would otherwise affect the performance of the semiconductor layer SC. In this implementation, the first portion 31 of the conductive pad 30 is located in the same film layer as the semiconductor layer SC of the first transistor T1, and the third portion 33 of the conductive pad 30 is located in the same film layer as the buffer layer and/or light-shielding layer LS.

In one technical solution corresponding to these embodiments, the first transistor T1 may have a top-bottom dual-gate structure, that is, the first transistor T1 includes a top gate G11 located on the side of the semiconductor layer SC away from the substrate 10 and a bottom gate G12 located on the side close to the substrate 10. In this implementation, the lead trace 20 is located in the same film layer as the top gate G11 of the first transistor T1. The first portion 31 of the conductive pad 30 is located in the same film layer as the semiconductor layer SC of the first transistor T1. The third portion 33 of the conductive pad 30 is located in the same film layer as the insulating layer between the bottom gate G12 of the first transistor T1 and the semiconductor layer SC. In this implementation, the conductive pad 30 may also include a second portion 32, which may be located in the same film layer as the bottom gate G12 of the first transistor T1.

FIG. 18 is a schematic cross-sectional view of a partial region of a display substrate provided in some embodiments of the present application.

In a technical solution corresponding to these embodiments, as shown in FIG. 18, the first portion 31 of the conductive pad 30 is located in the same film layer as the semiconductor layer SC of the first transistor T1. The thickness of the first portion 31 in a direction perpendicular to the plane where the display substrate 01 is located is greater than the thickness of the semiconductor layer SC of the first transistor T1 in a direction perpendicular to the plane where the display substrate 01 is located. That is, the semiconductor layer SC included in the first transistor T1 is a first structure 30′ located in the same film layer as the first portion 31, and the thickness H1 of the first portion 31 in a direction perpendicular to the plane where the display substrate 01 is located is greater than the thickness H2 of the first structure 30′ in a direction perpendicular to the plane where the display substrate 01 is located.

In this technical solution, at least some of the process steps for manufacturing the first portion 31 are the same as those for manufacturing the semiconductor layer SC of the first transistor T1, reducing the difficulty of manufacturing the first portion 31. Furthermore, the thickness H1 of the first portion 31 is greater than the thickness H2 of the semiconductor layer SC of the first transistor T1, so that a thicker conductive pad 30 can be obtained, and a weak point P1 for electrostatic discharge can be more easily obtained.

In one implementation, the conductive pad 30 comprises at least two portions stacked in a direction perpendicular to the plane where the display substrate 01 is located, and the thickness of two portions each may be greater than the thickness of the structure in the second region R2 that is located in the same film layer as any one of the two portions. For example, in addition to a first portion 31 on the same layer as the semiconductor layer SC of the first transistor T1, the conductive pad 30 also includes a second portion 32 on the same layer as the bottom gate G12 of the first transistor T1. The thickness of the second portion 32 in a direction perpendicular to the plane where the display substrate 01 is located is greater than the thickness of the bottom gate G12 of the first transistor T1 in a direction perpendicular to the plane where the display substrate 01 is located. For example, in addition to the first portion 31 on the same layer as the semiconductor layer SC of the first transistor T1, the conductive pad 30 also includes a third portion 33 on the same layer as the buffer layer and/or light-shielding layer LS on the side of the semiconductor layer SC of the first transistor T1 facing the substrate 10. The thickness of the third portion 33 in a direction perpendicular to the plane where the display substrate 01 is located is greater than the thickness of the buffer layer and/or light-shielding layer LS in a direction perpendicular to the plane where the display substrate 01 is located.

FIG. 19 is a schematic cross-sectional view of a partial region of a display substrate provided in some embodiments of the present application.

In one technical solution corresponding to these embodiments, as shown in FIG. 19, the first portion 31 of the conductive pad 30 is located in the same film layer as the semiconductor layer SC of the first transistor T1. The sidewall inclination angle α of the first portion 31 is greater than the sidewall inclination angle β of the semiconductor layer SC included in the first transistor T1. That is, the semiconductor layer SC included in the first transistor T1 is a first structure 30′ located in the same film layer as the first portion 31, and the sidewall inclination angle α of the first portion 31 is greater than the sidewall inclination angle β of the first structure 30′.

In this technical solution, at least some of the process steps for manufacturing the first portion 31 are the same as those for manufacturing the semiconductor layer SC of the first transistor T1, reducing the difficulty of manufacturing the first portion 31. Furthermore, the sidewall inclination angle α of the first portion 31 is greater than the sidewall inclination angle β of the semiconductor layer SC of the first transistor T1, so that the conductive pad 30 having at least parts of sidewalls with a relatively large inclination angle can be obtained, and a weak point P1 for electrostatic discharge can be more easily obtained.

In one implementation, the conductive pad 30 includes at least two portions stacked in a direction perpendicular to the plane where the display substrate 01 is located. The sidewall inclination angle of two portions each may be greater than the sidewall inclination angle of structure in the second region R2 that is located on the same film layer as any one the two portions. For example, in addition to a first portion 31 located on the same layer as the semiconductor layer SC of the first transistor T1, the conductive pad 30 includes a second portion 32 located on the same layer as the bottom gate G12 of the first transistor T1. The sidewall inclination angle of the second portion 32 is greater than the sidewall inclination angle of the bottom gate G12 of the first transistor T1. For example, in addition to the first portion 31 located on the same layer as the semiconductor layer SC of the first transistor T1, the conductive pad 30 includes a third portion 33 located on the same layer as the buffer layer and/or light-shielding layer LS on the side of the semiconductor layer SC of the first transistor T1 facing the substrate 10. The sidewall inclination angle of the third portion 33 is greater than the sidewall inclination angle of the buffer layer and/or light-shielding layer LS.

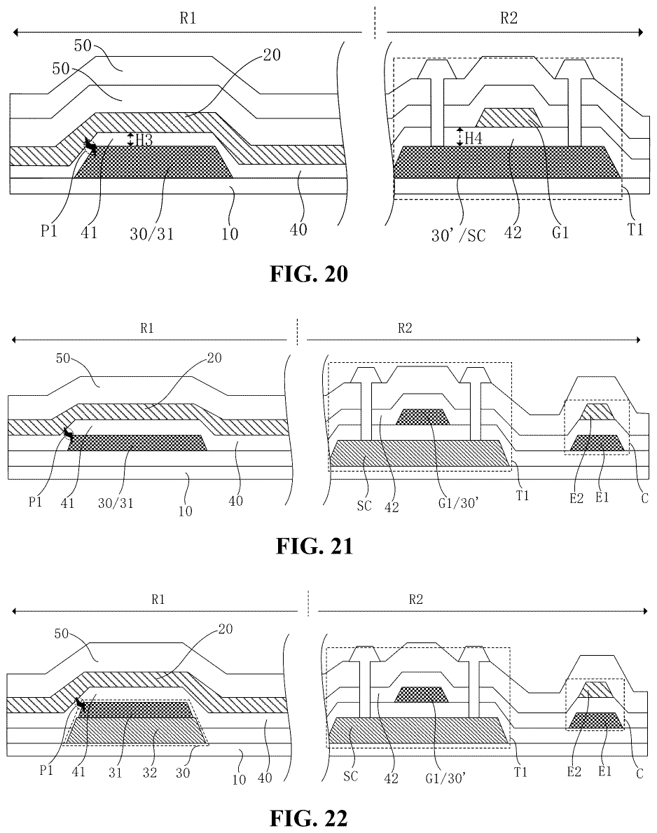

FIG. 20 is a schematic cross-sectional view of a partial region of a display substrate provided in some embodiments of the present application.

In one technical solution corresponding to these embodiments, as shown in FIG. 20, the thickness H3 of the portion of the first insulating layer 40 located between the conductive pad 30 and the lead trace 20 is less than the thickness H4 of the portion of the first insulating layer 40 located between the gate G1 of the first transistor T1 and the semiconductor layer SC. That is, the insulating layer between the conductive pad 30 and the lead trace 20 is the first insulating portion 41, which is the same layer as the second insulating portion 42 between the gate G1 of the first transistor T1 and the semiconductor layer SC. Furthermore, the thickness H3 of the first insulating portion 41 is less than the thickness H4 of the second insulating portion 42.

In this technical solution, at least some of the process steps for manufacturing the first insulating portion 41 and at least some of the process steps for manufacturing the second insulating portion 42 are the same, reducing the difficulty in manufacturing the first insulating portion 41. Furthermore, the thickness H3 of the first insulating portion 41 is less than the thickness H4 of the second insulating portion 42, so that a weak point P1 for electrostatic discharge can be easily obtained.

FIG. 21 is a schematic cross-sectional view of a partial region of a display substrate provided in some embodiments of the present application.

In some embodiments of the present application, as shown in FIG. 21, the display substrate 01 includes not only a first transistor T1 but also a capacitor C. If the display substrate 01 includes a pixel circuit, the pixel circuit may include the first transistor T1 and the capacitor CC. The first transistor T1 includes a gate G1, and the capacitor C includes a first electrode plate E1 and a second electrode plate E2, wherein the first electrode plate E1 and the gate G1 are located in the same film layer. At least a portion of the conductive pad 30 is located in the same film layer as the first electrode plate E1, and at least a portion of the lead trace 20 is located in the same film layer as the second electrode plate E2. Therefore, at least a portion of the conductive pad 30 is manufactured simultaneously with the gate G1 of the first transistor T1 and the first electrode plate E1 of the capacitor C, and at least a portion of the lead trace 20 is manufactured simultaneously with the second electrode plate E2 of the capacitor C. For example, as shown in FIG. 21, the conductive pad 30 includes a first portion 31, the first portion 31 is located in the same conductive film layer as the gate G1 and the first electrode plate E1, and the lead trace 20 is located in the same conductive film layer as the second electrode plate E2.

To ensure the capacitance of capacitor C, the first electrode plate E1 and the second electrode plate E2 of the capacitor C typically comprise only an inorganic material film layer as an insulating layer and the insulating layer has a relatively thin thickness. Therefore, in these embodiments, at least a portion of the conductive pad 30 is located in the same film layer as the first electrode plate E1 of the capacitor C, the first insulating layer 40 is located in the same film layer as the insulating layer between the first electrode plate E1 and the second electrode plate E2, and at least a portion of the lead trace 20 is located in the same film layer as the second electrode plate E2 of the capacitor C, so that a weak point P1 for electrostatic discharge between the lead trace 20 and the conductive pad 30 can be easily obtained without increasing the difficulty of the process.

FIG. 22 is a schematic cross-sectional view of a partial region of a display substrate provided in some embodiments of the present application.

In a technical solution corresponding to these embodiments, as shown in FIG. 22, the conductive pad 30 includes a first portion 31 and a second portion 32. The first portion 31 is a conductor and is located in the same film layer as the first electrode plate E1 of capacitor C, while the second portion 32 is a semiconductor and is located in the same film layer as the semiconductor layer SC of the first transistor T1.

In one implementation, when the first transistor T1 includes a top gate G11 located on the side of the semiconductor layer SC away from the substrate 10 and a bottom gate G12 located on the side close to the substrate 10, the conductive pad 30 may include a first portion 31 located in the same film layer as the top gate G11, a second portion 32 located in the same film layer as the semiconductor layer SC of the first transistor T1, and other portions located in the same film layer as the bottom gate G12.

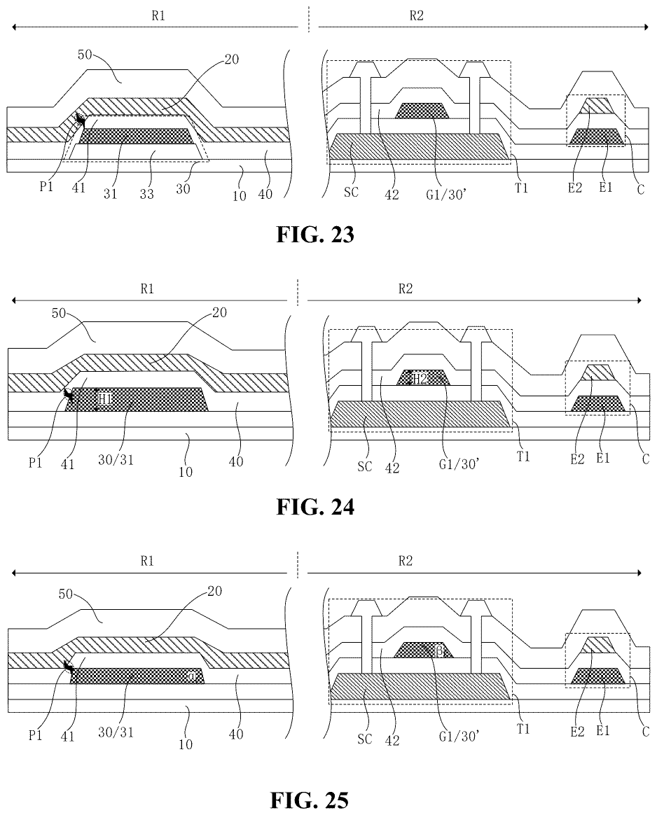

FIG. 23 is a schematic cross-sectional view of a partial region of a display substrate provided in some embodiments of the present application.

In a technical solution corresponding to these embodiments, as shown in FIG. 23, the conductive pad 30 includes a first portion 31 and a third portion 33. The first portion 31 is a conductor and located in the same film layer as the first electrode plate E1 of the capacitor C. The third portion 33 is an insulator and located in the same film layer as the insulating layer between the semiconductor layer SC and the gate G1.

In one implementation, when the first transistor T1 includes a top gate G11 located on the side of the semiconductor layer SC away from the substrate 10 and a bottom gate G12 located on the side close to the substrate 10, the conductive pad 30 may include a first portion 31 located in the same film layer as the top gate G11, a second portion 32 located in the same film layer as the bottom gate G12, and a third portion 33 located in the same film layer as the insulating layer between the semiconductor layer SC and the gate G1.

In one implementation, when the insulating layer between the film layer where the semiconductor layer SC of the first transistor T1 is located and the substrate 10 may include a buffer layer and/or a light-shielding layer, the conductive pad 30 may include a first portion 31 located in the same film layer as the top gate G11, a third portion 33 located in the same film layer as the insulating layer between the semiconductor layer SC and the gate G1, and other portions located in the same film layer as the buffer layer and/or the light-shielding layer.

Furthermore, when the first portion 31 is a conductor and is located in the same film layer as the first electrode plate E1 of the capacitor C, the third portion 33 of the conductive pad 30 can be located in the same film layer as the buffer layer and/or light-shielding layer. Alternatively, when the first transistor T1 includes a top and bottom dual gate, the third portion 33 of the conductive pad 30 may be located in the same film layer as the insulating layer between the bottom gate of the first transistor T1 and the semiconductor layer SC, which is not repeated here.

FIG. 24 is a schematic cross-sectional view of a partial region of a display substrate provided in some embodiments of the present application.

In one technical solution corresponding to these embodiments, as shown in FIG. 24, the first portion 31 of the conductive pad 30 is located in the same film layer as the first electrode plate E1 of the capacitor C. The thickness of the first portion 31 in a direction perpendicular to the plane where the display substrate 01 is located is greater than the thickness of the first electrode plate E1 of the first capacitor C in a direction perpendicular to the plane where the display substrate 01 is located. That is, the first electrode E1 of capacitor C is a first structure 30′ located in the same film layer as the first portion 31, and the thickness H1 of the first portion 31 in a direction perpendicular to the plane where the display substrate 01 is located is greater than the thickness H2 of the first structure 30′ in a direction perpendicular to the plane where the display substrate 01 is located.

In this technical solution, at least some of the process steps for manufacturing the first portion 31 are the same as those for manufacturing the first electrode E1 of capacitor C, reducing the difficulty of manufacturing the first portion 31. Furthermore, the thickness H1 of the first portion 31 is greater than the thickness H2 of the first electrode E1 of capacitor C, a thicker conductive pad 30 can be obtained, and a weak point P1 for electrostatic discharge can be more easily obtained.

In one implementation, the conductive pad 30 comprises at least two portions stacked in a direction perpendicular to the plane where the display substrate 01 is located. The thickness of two portions each can be greater than the thickness of the structure in the second region R2 that is located in the same film layer as any one of two portions. For example, in addition to a first portion 31 on the same layer as the first electrode plate E1 of the capacitor C, the conductive pad 30 includes a second portion 32 on the same layer as the semiconductor layer SC of the first transistor T1, wherein the thickness of the second portion 32 in a direction perpendicular to the plane where the display substrate 01 is located is greater than the thickness of the semiconductor layer SC of the first transistor T1 in a direction perpendicular to the plane where the display substrate 01 is located. For example, in addition to the first portion 31 on the same layer as the first electrode plate E1 of the capacitor C, the conductive pad 30 includes a third portion 33 on the same layer as the insulating structure on the side of the semiconductor layer SC of the first transistor T1 facing the substrate 10, wherein the thickness of the third portion 33 in a direction perpendicular to the plane where the display substrate 01 is located is greater than the thickness of the insulating structure in a direction perpendicular to the plane where the display substrate 01 is located.

FIG. 25 is a schematic cross-sectional view of a partial region of a display substrate provided in some embodiments of the present application.

In a technical solution corresponding to these embodiments, as shown in FIG. 25, the first portion 31 of the conductive pad 30 is located in the same film layer as the first electrode plate E1 of the capacitor C, and the sidewall inclination angle of the first portion 31 is greater than the sidewall inclination angle of the first electrode E1 of the capacitor C. That is, the first electrode E1 of capacitor C is a first structure 30′located in the same film layer as the first portion 31, and the sidewall inclination angle α of the first portion 31 is greater than the sidewall inclination angle β of the first structure 30′.

In this technical solution, at least some of the process steps for manufacturing the first portion 31 are the same as those for manufacturing the first electrode E1 of capacitor C, reducing the difficulty of manufacturing the first portion 31. Furthermore, the sidewall inclination angle α of the first portion 31 is greater than the sidewall inclination angle β of the first electrode E1 of capacitor C, so that the conductive pad 30 having at least parts of sidewalls with a relatively large inclination angle can be obtained, and a weak point P1 for electrostatic discharge can be more easily obtained.

In one implementation, the conductive pad 30 comprises at least two portions stacked in a direction perpendicular to the plane where the display substrate 01 is located. The sidewall inclination angle of two portions each can be greater than the sidewall inclination angle of the structure in the second region R2 that is located in the same film layer with any one of two portions. For example, in addition to a first portion 31 on the same layer as the first electrode plate E1 of the capacitor C, the conductive pad 30 includes a second portion 32 on the same layer as the semiconductor layer SC of the first transistor T1. The sidewall inclination angle of the second portion 32 is greater than the sidewall inclination angle of the semiconductor layer SC of the first transistor T1. For example, in addition to the first portion 31 on the same layer as the first electrode plate E1 of the capacitor C, the conductive pad 30 also includes a third portion 33 on the same layer as the insulating structure on the side of the semiconductor layer SC of the first transistor T1 facing the substrate 10. The sidewall inclination angle of the third portion 33 is greater than the sidewall inclination angle of the insulating structure.

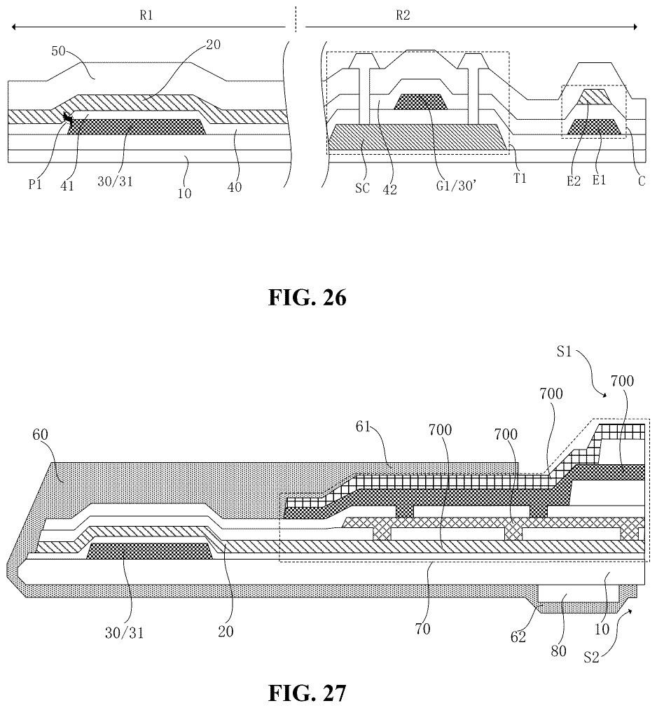

FIG. 26 is a schematic cross-sectional view of a partial region of a display substrate provided in some embodiments of the present application.

In one technical solution corresponding to these embodiments, as shown in FIG. 26, the thickness of the portion of the first insulating layer 40 located between the conductive pad 30 and the lead trace 20 is less than the thickness of the portion of the first insulating layer 40 located between the first electrode plate E1 and the second electrode plate E2 of the capacitor C. That is, the insulating layer between the conductive pad 30 and the lead trace 20 is a first insulating portion 41, which is the same layer as the second insulating portion 42 between the first electrode plate E1 and second electrode plate E2 of the capacitor C. The thickness H3 of the first insulating portion 41 is less than the thickness H4 of the second insulating portion 42.

In this technical solution, at least some of the process steps for manufacturing the first insulating portion 41 and at least some of the process steps for manufacturing the second insulating portion 42 are the same, reducing the difficulty of manufacturing the first insulating portion 41. Furthermore, the thickness H3 of the first insulating portion 41 is less than the thickness H4 of the second insulating portion 42, so that a weak point P1 for electrostatic discharge can be more easily obtained.

In some embodiments of the present application, the display substrate 01 further includes a second insulating layer 50, which is located between different conductive film layers and is a different layer from the first insulating layer 40. In a direction perpendicular to the plane where the display substrate 01 is located, the thickness of the first insulating layer 40 is less than that of the second insulating layer 50. In the embodiments of the present application, the thickness of the first insulating layer 40 located between the lead trace 20 and the conductive pad 30 is smaller than the thickness of all other insulating layers or parts of the insulating layers. Therefore, it is easier to obtain the weak point P1 for electrostatic discharge.

As shown in FIGS. 13 to 20, the first insulating layer 40 is located between the semiconductor layer SC and the gate G1 of the first transistor T1. The second insulating layer 50 is located on the side of the film layer where the gate G1 of the first transistor T1 is located that is away from the substrate 10. The thickness of the second insulating layer 50 in a direction perpendicular to the plane where the display substrate 01 is located is greater than the thickness of the first insulating layer 40 in a direction perpendicular to the plane where the display substrate 01 is located.

As shown in FIGS. 21 to 26, the first insulating layer 40 is located between the first electrode plate E1 and the second electrode plate E2 of the capacitor C. The second insulating layer 50 is located on the side of the film layer where the second electrode plate E2 is located that is away from the substrate 10. The thickness of the second insulating layer 50 in a direction perpendicular to the plane where the display substrate 01 is located is greater than the thickness of the first insulating layer 40 in a direction perpendicular to the plane where the display substrate 01 is located.

FIG. 27 is a schematic cross-sectional view in a direction of B1-B2 in FIG. 3.

Combining FIGS. 3 and 27, to enable electrical connection between the functional signal lines 20′ and the IC and/or flexible circuit board, the display substrate 01 further includes a transfer electrode block 70. The transfer electrode block 70 is located in the first region R1 and serves as a transfer portion between the functional signal line 20′ and the IC and/or flexible circuit board. The transfer electrode block 70 is located in the first region R1 and is connected to the functional signal line 20′.

As shown in FIG. 27, the transfer electrode block 70 includes at least two transfer electrodes 700 arranged in a direction perpendicular to the plane where the display substrate 01 is located and located on different conductive film layers. Since the transfer electrode block 70 comprises at least two stacked transfer electrodes 700, these stacked transfer electrodes 700 can be located on the same layer as at least some functional signal lines 20′ located on different film layers of the display substrate 01, facilitating connection between the functional signal lines 20′ and the transfer electrode block 70. For example, if the transfer electrode block 70 to which a data line is connected includes a transfer electrode 700 located on the same layer as the data line, the data line and the transfer electrode 700 in the transfer electrode block 70 remain connected after being etched, there is no need to transfer through other structures, which reduces the process difficulty and improves the process reliability.

In addition, the lead trace 20 can include a portion located on the same conductive film layer as at least one transfer electrode 700 in the transfer electrode block 70, facilitating electrical connection between the lead trace 20 and the functional signal line 20′ via the transfer electrode block 70. For example, as shown in FIG. 27, the lead trace 20 and the transfer electrode 700 at the bottommost of the transfer electrode block 70 and located in the same conductive film layer as the gate of the first transistor T1 are located in the same conductive film layer. Therefore, the lead trace 20 and the transfer electrode 700 in the transfer electrode block 70 remain connected after being etched, there is no need to transfer through other structures, which reduces the process difficulty and improves the process reliability.

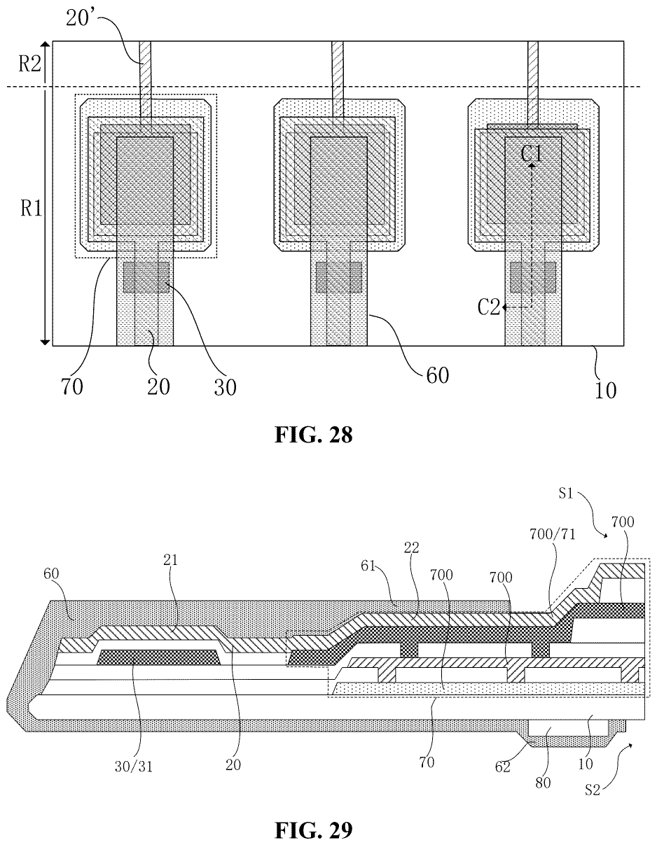

FIG. 28 is a detailed schematic diagram of a partial region shown in FIGS. 1 and 2, and FIG. 29 is a schematic cross-sectional view in a direction of C1-C2 in FIG. 28.

Referring to FIGS. 28 and 29, the lead trace 20 is electrically connected to the transfer electrode block 70, and at least a portion of the lead trace 20 is located in the same film layer as the first transfer electrode 71. For example, as shown in FIG. 29, when the lead trace 20 only includes structures located in one conductive film layer, the lead trace 20 can be located in the same film layer as the first transfer electrode 71.

In some embodiments of the present application, as shown in FIGS. 27 and 29, the display substrate 01 includes a light-emitting surface S1 and a backlight surface S2. The light-emitting surface S1 is the side of the display substrate 01 that displays the display image to the user. In order to reduce the border of the display substrate 01, the IC and/or flexible circuit board bound to the display substrate 01 are bound to the display substrate 01 on the backlight surface S2 side of the display substrate 01. The display substrate 01 also includes a connecting electrode 60 and an external electrode block 80, wherein the transfer electrode block 70 and the external electrode block 80 are located on different sides of the substrate 10. As shown in FIGS. 27 and 29, the external electrode block 80 is located on the backlight surface S2 side of the display substrate 01, and the connecting electrode 60 is electrically connected to the transfer electrode block 70 and the external electrode block 80. Then, the external electrode block 80 is electrically connected to the functional signal line 20′ through the connecting electrode 60. Specifically, the end portion 61 of the connecting electrode 60 located on the light-emitting surface S1 side of the display substrate 01 contacts the transfer electrode block 70 on the light-emitting surface S1 side of the display substrate 01, the end portion 62 of the connecting electrode 60 located on the backlight surface S2 side of the display substrate 01 contacts the external electrode block 80 on the backlight surface S2 side of the display substrate 01 or serves as the external electrode block 80, and the portion of the connecting electrode 60 between the end portion 61 on the light-emitting surface S1 side of the display substrate 01 and the end portion 62 on the backlight surface S2 side of the display substrate 01 is routed on the sidewall of the display substrate 01.

In addition, the backlight surface S2 side of the display substrate 01 may include an external electrode block 80 manufactured using a semiconductor process. This external electrode block 80 may include at least two conductive structures stacked in a direction perpendicular to the plane where the display substrate 01 is located. Alternatively, the end portion 62 of the connecting electrode 60 located on the backlight surface S2 side of the display substrate 01 may serve as the external electrode block 80 coupled to an IC and/or a flexible circuit board.

The transfer electrode block 70 is an electrode block that electrically connects the external electrode block 80 and the lead traces to the functional signal lines 20′. The width of the transfer electrode block 70 is generally greater than the width of the signal line and lead trace each, which is conducive to improving the contact yield between the connecting electrode 60 and the transfer electrode block 70.

In some embodiments of the present application, as shown in FIG. 29, the transfer electrode block 70 includes a first transfer electrode 71. The first transfer electrode 71 is located on the side of the other transfer electrode 700 away from the substrate 10, that is, the first transfer electrode 71 is the transfer electrode 700 in the transfer electrode block 70 that is farthest from the substrate 10. When the transfer electrode block 70 contacts the connecting electrode 60, it is mainly the first transfer electrode 71 in the transfer electrode block 70 that contacts the connecting electrode 60. Furthermore, at least a portion of the lead trace 20 is disposed on the same layer as the first transfer electrode 71, therefore, when the connecting electrode 60 contacts the first transfer electrode 71, the connecting electrode 60 also contacts the portion of the lead trace 20, which can ensure the electrical connection yield between the connecting electrode 60 and the transfer electrode block 70 and reduce the impedance between the connecting electrode 60 and the transfer electrode block 70. In one technical solution, as shown in FIG. 29, the connecting electrode 60 is in contact with and connected to the lead trace 20.

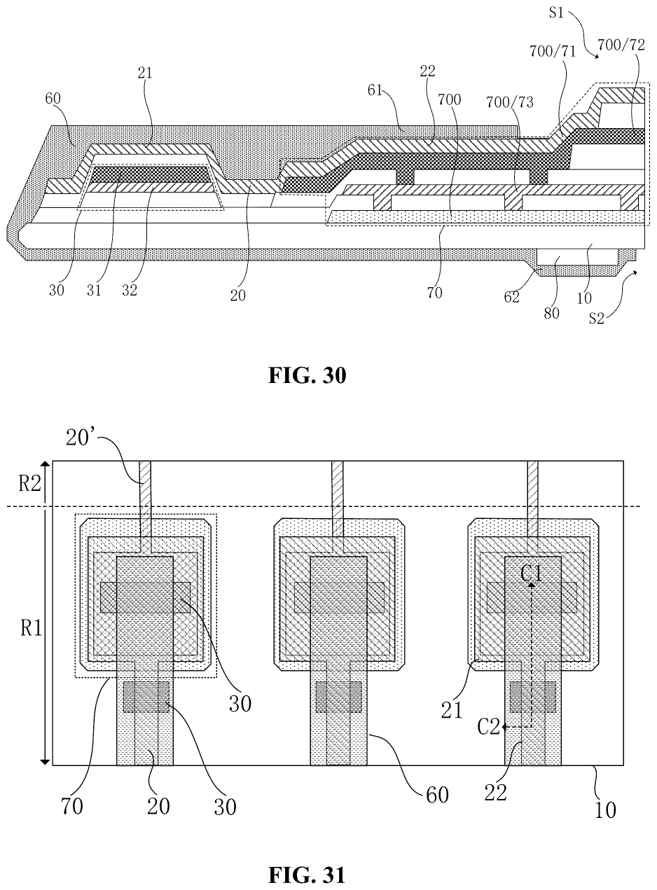

FIG. 30 is a schematic cross-sectional view in a direction of C1-C2 in FIG. 28.

In one technical solution corresponding to these embodiments, as shown in FIG. 30, the transfer electrode block 70 further includes a second transfer electrode 72 and a third transfer electrode 73. The second transfer electrode 72 and the third transfer electrode 73 are located on the side of the first transfer electrode 71 close to the substrate 10. Therefore, the steps for manufacturing the second transfer electrode 72 and the third transfer electrode 73 are performed before manufacturing the first transfer electrode 71.

The conductive pad 30 includes a portion located in the same film layer as the second transfer electrode 72 and a portion located in the same film layer as the third transfer electrode 73. For example, as shown in FIG. 31, the first portion 31 of the conductive pad 30 is located in the same layer as the second transfer electrode 72 of the transfer electrode block 70, and the second portion 32 of the conductive pad 30 is located in the same layer as the third portion 73 of the transfer electrode 70. Furthermore, because at least a portion of the lead trace 20 is located in the same film layer as the first transfer electrode 71 of the transfer electrode block 70, at least a portion of the conductive pad 30 and at least a portion of the lead trace can be obtained when manufacturing the transfer electrode block 70, thereby saving process steps.

In some embodiments of the present application, as shown in FIGS. 29 and 30, the lead trace 20 includes a first lead portion 21 and a second lead portion 22, with the first lead portion 21 and the second lead portion 22 being electrically connected. The first lead portion 21 of the lead trace 20 is reused as at least one transfer electrode 700 included in the transfer electrode block 70. For example, as shown in FIGS. 29 and 30, the first lead portion 21 is reused as the first transfer electrode 71, while the second lead portion 22 does not overlap the transfer electrode block 70 in a direction perpendicular to the plane where the display substrate 01 is located. The lead trace 20 is electrically connected to the transfer electrode block 70 via the first lead portion 21, and the second lead portion 22 can be located on the side of the first lead portion 21 away from the second region R2.

FIG. 31 is a detailed schematic diagram of a partial region shown in FIGS. 1 and 2.

In these embodiments, as shown in FIG. 31, at least parts of the first lead portions 21 overlap the conductive pads 30 in a direction perpendicular to the plane where the display substrate 01 is located, which ensures that at least parts of the transfer electrode block 70 and the lead traces 20 electrically connected to these transfer electrode blocks 70 overlap the conductive pad 30 in a direction perpendicular to the plane where the display substrate 01 is located. Therefore, a weak point P1 for electrostatic discharge can be obtained in the region of the transfer electrode block 70 on the display substrate 01, fully utilizing the space in the first region R1 of the display substrate 01.

In one technical solution corresponding to these embodiments, at least parts of the second lead portions 22 overlap the conductive pads 30 in a direction perpendicular to the plane where the display substrate 01 is located. For example, as shown in FIG. 31, the first lead portion 21 and the second lead portion 22 each overlap the conductive pad 30 in a direction perpendicular to the plane where the display substrate 01 is located.

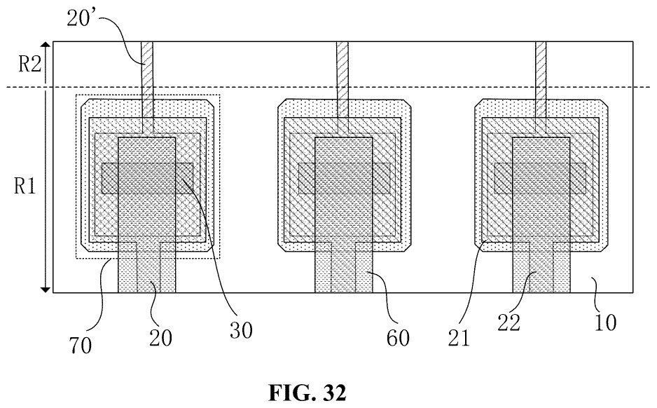

FIG. 32 is a detailed schematic diagram of a partial region shown in FIGS. 1 and 2.

In one technical solution corresponding to these embodiments, as shown in FIG. 32, the conductive pad 30 overlaps the first lead portion 21 in a direction perpendicular to the plane where the display substrate 01 is located. That is, the portion of the lead trace 20 that overlaps the conductive pad in a direction perpendicular to the plane where the display substrate 01 is located only includes the portion of the transfer electrode 700 reused as the transfer electrode block 70. In this way, the extension length of the second lead portion 22 of the lead trace 20 is not restricted by the conductive pad 30, thereby facilitating a narrower width of the first region R1.

In some embodiments of the present application, referring to FIGS. 27, 29, and 30 in conjunction with FIGS. 5 and 6, at least parts of edges of the lead traces 20 away from the second region R2 partially coincide with the edge of the display substrate 01. It should be noted that the lead traces 20 coinciding with the edge of the display substrate 01 refer to the lead traces 20 coinciding with the edge of the substrate 10 in the display substrate 01 and the multiple stacked film layers manufactured using a semiconductor process.

The connecting electrode 60 is manufactured after the stacked film layers are manufactured using a semiconductor process on the substrate 10. Before manufacturing the connecting electrode 60, the display substrate 01 obtained initially needs to be subjected to edge grinding process, so that the edges of the substrate 10 and the multiple stacked film layers manufactured using the semiconductor process form chamfered edges. When manufacturing the connecting electrode 60, the continuity and manufacturing yield of the connecting electrode 60 at the position of the display substrate 01 can be ensured; in addition, the display substrate 01 can have a narrower border.

However, during the edge grinding process, the friction between the required tools, such as a grinding rod or grinding wheel, and the display substrate 01 generates static electricity. Furthermore, the substrate of the display substrate 01 may be a glass substrate, which is more susceptible to static electricity during the edge grinding process. This static electricity can be introduced into the display substrate 01, causing damage to the components of the display substrate 01 and resulting in a loss of process yield.

After edge grinding process, at least parts of the edges of the lead traces 20 away from the second region R2 coincide with the edge of the initially obtained display substrate 01. In other words, during the edge grinding process, at least parts of the edges of the lead trace 20 are exposed at the edge of the display substrate 01. During edge grinding process, the grinding of the lead trace 20 generates static electricity, and at least some of the static electricity generated by structures such as the glass substrate is also introduced into the lead trace 20. In the embodiments provided by the present application, the lead trace 20 and the conductive pad 30 overlap in a direction perpendicular to the plane where the display substrate 01 is located, effectively discharging static electricity on the lead trace 20.

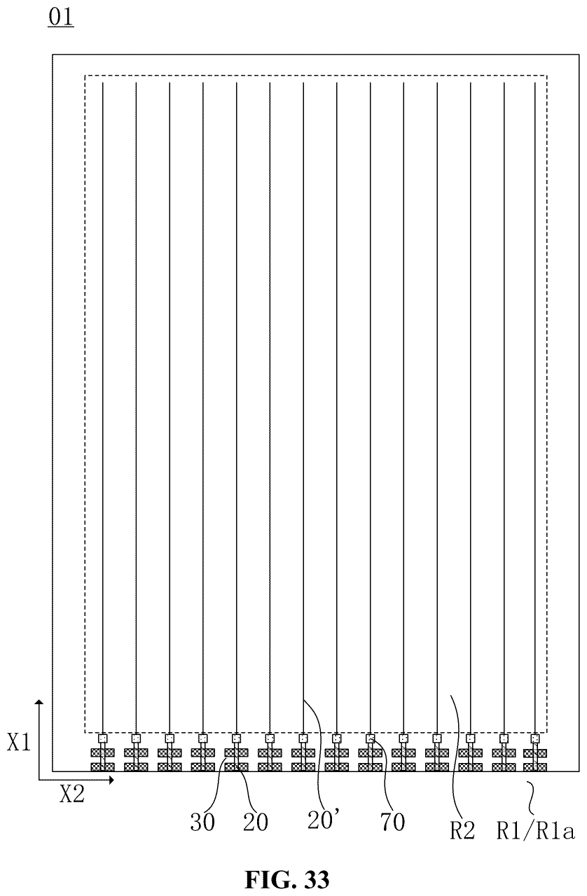

FIG. 33 is a detailed schematic diagram of a partial region shown in FIGS. 1 and 2.

In some embodiments of the present invention, as shown in FIG. 33, at least parts of edges of at least parts of the conductive pads 30 away from the second region R2 partially coincide with an edge of the display substrate 01. It should be noted that the conductive pads 30 coinciding with the edge of the display substrate 01 refers to the conductive pads 30 coinciding with the edges of the substrate 10 in the display substrate 01 and the multiple stacked film layers manufactured using a semiconductor process. On the one hand, when performing the above-mentioned edge grinding process, the edge grinding stop position can be the position where the conductive pad 30 is disposed, so that the first region R1 has a relatively small width; on the other hand, the conductive pad 30 is as close to the edge of the display substrate 01 as possible, so that the weak point P1 is located at the edge of the display substrate 01 as much as possible, thereby allowing at least part of the static electricity on the display substrate 01 to be discharged at the weak point P1 at the edge of the display substrate 01.

In some technical solutions, as shown in FIG. 33, at least parts of edges of the conductive pads 20 away from the second region R2 partially coincide with the edge of the display substrate 01, and at least parts of edges of the lead traces 20 away from the second region R2 partially coincide with an edge of the display substrate 01.

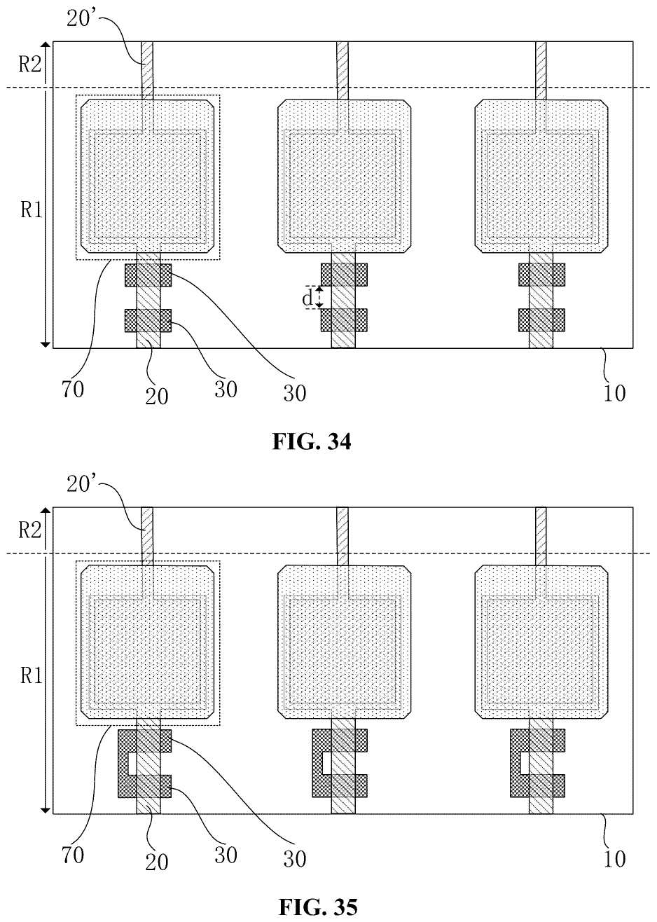

FIG. 34 is a detailed schematic diagram of a partial region shown in FIGS. 1 and 2.

In some embodiments of the present application, as shown in FIGS. 32 and 34, the lead traces 20 overlap at least two conductive pads 30 in a direction perpendicular to the plane where the display substrate 01 is located. The location of the lead traces 20 may correspond to at least two weak points P1 for electrostatic discharge.

It should be noted that at least parts of the lead traces 20 in the display substrate 01 overlap at least two conductive pads 30 in a direction perpendicular to the plane where the display substrate 01 is located. That is, all of the lead traces 20 in the display substrate 01 may overlap multiple conductive pads 30 in a direction perpendicular to the plane where the display substrate 01 is located; alternatively, some of the lead traces 20 in the display substrate 01 may overlap multiple conductive pads 30 in a direction perpendicular to the plane where the display substrate 01 is located. The present application does not limit whether other lead traces 20 overlap or do not overlap a single conductive pad 30 in a direction perpendicular to the plane where the display substrate 01 is located.

It should also be noted that, as shown in FIG. 32, among the at least two conductive pads 30 overlapping the same lead trace 20 in a direction perpendicular to the plane where the display substrate 01 is located, at least one of the at least two conductive pads 30 may overlap the first lead portion 21 and at least one may overlap the second lead portion 22. Alternatively, as shown in FIG. 34, among the at least two conductive pads 30 overlapping the same lead trace 20 in a direction perpendicular to the plane where the display substrate 01 is located, the at least two conductive pads 30 may overlap the second lead portion 22.

In one technical solution corresponding to these embodiments, the distance between two adjacent conductive pads 30 that overlap the same lead trace 20 is greater than or equal to 2.5 μm. For example, as shown in FIG. 34, among the multiple conductive pads 30 that overlap the same lead trace 20, the multiple conductive pads 30 are arranged along the extension direction of the lead trace 20, and the distance between adjacent conductive pads 30 is d, where d≥2.5 μm.

When the distance between two adjacent conductive pads 30 overlapping the same lead trace 20 is greater than or equal to 2.5 μm, the first insulating layer 40 forms an effective electrostatic discharge weak point P1 on the adjacent sidewalls of the two conductive pads 30, preventing the risk of the thickness of the first insulating layer 40 between the two conductive pads 30 being significantly thinned.

In one technical solution corresponding to these embodiments, as shown in FIGS. 32 and 34, at least two adjacent conductive pads 30 overlapping the same lead trace 20 are separated, that is, there is no connection relationship between these conductive pads 30.

FIG. 35 is a detailed schematic diagram of a partial region shown in FIGS. 1 and 2, and FIG. 36 is a detailed schematic diagram of a partial region shown in FIGS. 1 and 2.

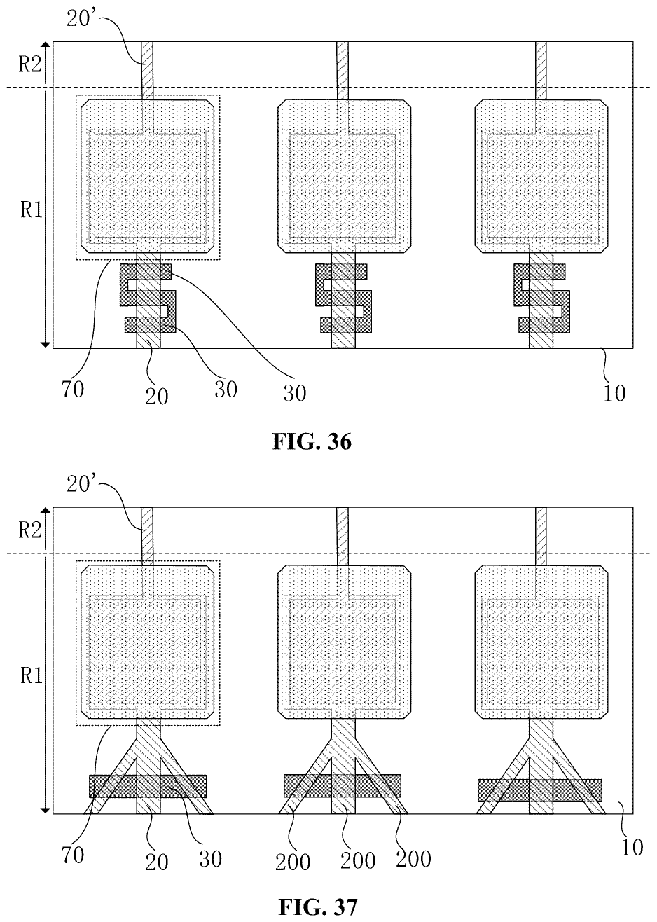

In one technical solution corresponding to these embodiments, at least two adjacent conductive pads 30 overlapping the same lead trace 20 are connected. For example, as shown in FIGS. 35 and 36, adjacent conductive pads 30 among the multiple conductive pads 30 overlapping the same lead trace 20 are connected. When the conductive pads 30 are connected, they more easily serve as paths for discharging static electricity from the lead trace 20.

As shown in FIG. 35, the connected conductive pads 30 can be U-shaped; as shown in FIG. 36, the connected conductive pads 30 can also be S-shaped. Furthermore, the connected conductive pads 30 can have other shapes.

FIG. 37 is a detailed schematic diagram of a partial region shown in FIGS. 1 and 2.

In one embodiment of the present application, as shown in FIG. 37, the lead trace 20 includes branch traces 200 extending in different directions. The branch traces 200 overlap the conductive pads 30 in a direction perpendicular to the plane where the display substrate 01 is located. In the embodiments of the present application, the lead trace 20 comprises a plurality of branch traces 200 respectively overlapping the conductive pads 30, wherein each branch trace 200 can become a path for discharging static electricity in the lead trace 20 and can obtain more weak points P1, which is conducive to the discharge of static electricity on the lead trace 20.

It should be noted that the branch traces 200 included in the same lead trace 20 can overlap different conductive pads 30 in a direction perpendicular to the plane where the display substrate 01 is located. Furthermore, the branch traces 200 included in the same lead trace 20 can also overlap the same conductive pad 30 in a direction perpendicular to the plane where the display substrate 01 is located. For example, as shown in FIG. 37, the lead trace 20 includes three branch traces 200, and these three branch traces 200 overlap the same conductive pad 30.

In some embodiments of the present application, at least parts of the lead traces 20 can be located in different conductive film layers, which can reduce the pressure of disposing too many lead traces 20 in the same conductive film layer, and avoid the risk of short circuit between adjacent lead traces 20.

In one implementation, at least two lead traces transmitting different signals are located in different conductive film layers. For example, the lead trace 20 transmitting the data voltage and the lead trace 20 transmitting the power supply voltage are located in different conductive film layers. When the lead traces 20 transmitting different signals are located in different film layers, the signal crosstalk between the lead traces 20 that transmit different signals can be reduced.

Furthermore, when the lead traces 20 include branch traces 200, the spatial area occupied by the lead traces 20 increases, and the distance between adjacent lead traces 20 in a direction parallel to the plane where the display substrate 01 is located decreases. At this time, disposing adjacent branch traces 200 in different conductive film layers can reduce the risk of short circuit, thereby reducing the risk of short circuit of the lead traces 20.

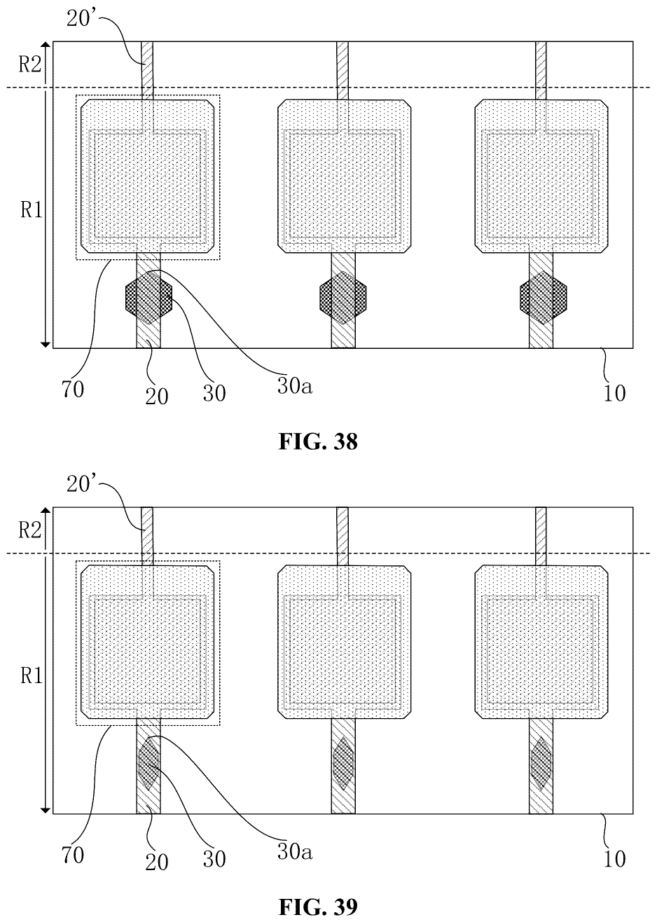

FIG. 38 is a detailed schematic diagram of a partial region shown in FIGS. 1 and 2.

In one embodiment of the present application, as shown in FIG. 38, the conductive pad 30 includes a first surface in contact with the first insulating layer 40. The shape of the first surface includes at least one vertex angle 30a. For example, as shown in FIG. 38, the orthographic projection of the first surface on the substrate 10 is a hexagon, and the first surface includes six vertex angles 30a. In this embodiment, the lead trace 20 overlaps at least one vertex angle 30a in a direction perpendicular to the plane where the display substrate 01 is located.

When the contact surface between the conductive pad 30 and the first insulating layer 40 includes a vertex angle 30a, the thickness of the first insulating layer 40 close to the vertex angle is thinner when ramping over the vicinity of the vertex angle 30a, forming a weak point P1 that is more likely to discharge the static electricity; furthermore, when the lead trace 20 overlaps at least one vertex angle 30 a, the lead trace 20 overlaps more sidewall positions of the conductive pad 30, that is, more weak points P1 can be obtained.

FIG. 39 is a detailed schematic diagram of a partial region shown in FIGS. 1 and 2, and FIG. 40 is a detailed schematic diagram of a partial region shown in FIGS. 1 and 2.

In a technical solution corresponding to this embodiment, the lead trace 20 covers the conductive pad 30 in a direction perpendicular to the plane where the display substrate 01 is located. In this technical solution, the lead trace 20 overlaps all sidewalls of the conductive pad 30, resulting in a significant number of weak points P1.

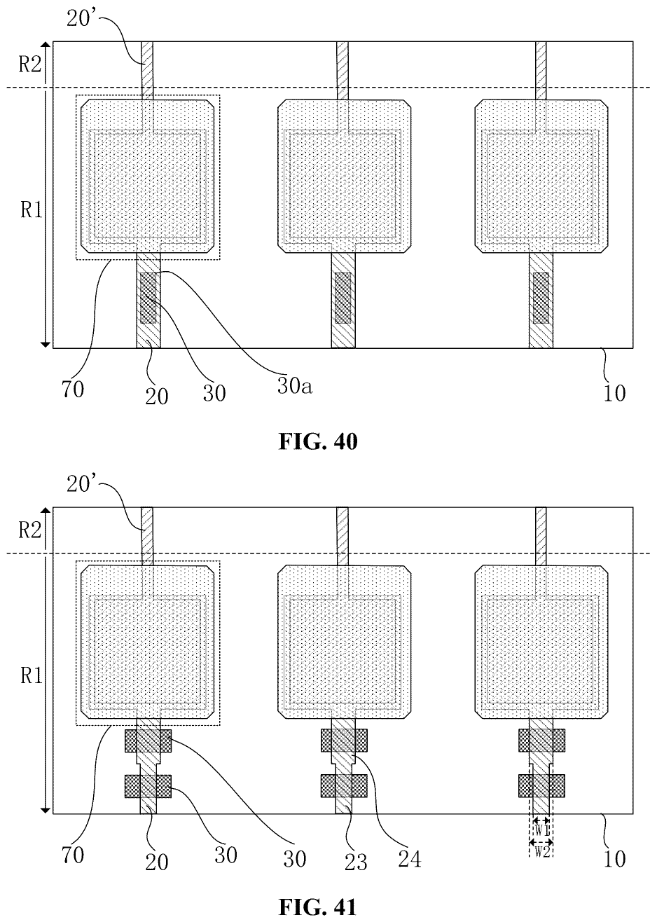

Furthermore, when the first surface of the conductive trace 30 is polygonal, the shape of the first surface can be a hexagon as shown in FIG. 39, or the shape of the first surface can also be a quadrilateral as shown in FIG. 40. In this case, the first surface includes multiple vertex angles 30a and the lead traces 20 cover the conductive pads 30 in a direction perpendicular to the plane where the display substrate 01 is located, so that more weak points P1 that are easier to discharge static electricity can be obtained.

FIG. 41 is a detailed schematic diagram of a partial region shown in FIG. 1 and FIG. 2.

In some embodiments of the present application, as shown in FIG. 41, the lead trace 20 includes a third lead portion 23 and a fourth lead portion 24. The third lead portion 23 is located on the side of the fourth lead portion 24 close to the edge of the display substrate 01. The width of the third lead portion 23 in a direction perpendicular to the extension direction of the lead trace 20 is smaller than the width of the fourth lead portion 24 in a direction perpendicular to the extension direction of the lead trace 20. The extension direction of the lead trace 20 is substantially parallel to the arrangement direction between the first region R1 in which the lead trace 20 is located and the connected second region R2. As shown in FIG. 41, the width of the third lead portion 23 is W1, and the width of the fourth lead portion 24 is W2, where W1 is less than W2.

A considerable amount of static electricity in the display substrate 01 diffuses inward from the edge of the display substrate 01. In this embodiment, the width of the third lead portion 23 closer to the edge of the display substrate 01 is smaller, so that static electricity can be discharged in the third lead portion 23. In other words, static electricity is discharged at a position closer to the edge of the display substrate 01, effectively protecting the functional components within the display substrate 01. Furthermore, the fourth lead portion 24 farther from the edge of the display substrate 01 has a larger width, which is conducive to the reliability of the transmission of the signal on the functional signal line 20′ via the lead trace 20. In particular, when the display substrate 01 needs to be grinded, the grinding position is located at the edge of the display substrate 01. Therefore, the static electricity density close to the edge of the display substrate 01 is higher, and this part of static electricity can be effectively discharged by the technical solution of this embodiment.

In one technical solution corresponding to this embodiment, at least the third lead portion 23 of the lead trace 20 overlaps the conductive pad 30 in a direction perpendicular to the plane where the display substrate 01 is located. In one implementation, as shown in FIG. 41, the third lead portion 23 of the lead trace 20 overlaps the conductive pad 30 in a direction perpendicular to the plane where the display substrate 01 is located, and the fourth lead portion 24 overlaps the conductive pad 30 in a direction perpendicular to the plane where the display substrate 01 is located. In another implementation, only the third lead portion 23 of the lead trace 20 overlaps the conductive pad 30 in a direction perpendicular to the plane where the display substrate 01 is located, and the fourth lead portion 24 does not overlap the conductive pad 30 in a direction perpendicular to the plane where the display substrate 01 is located.

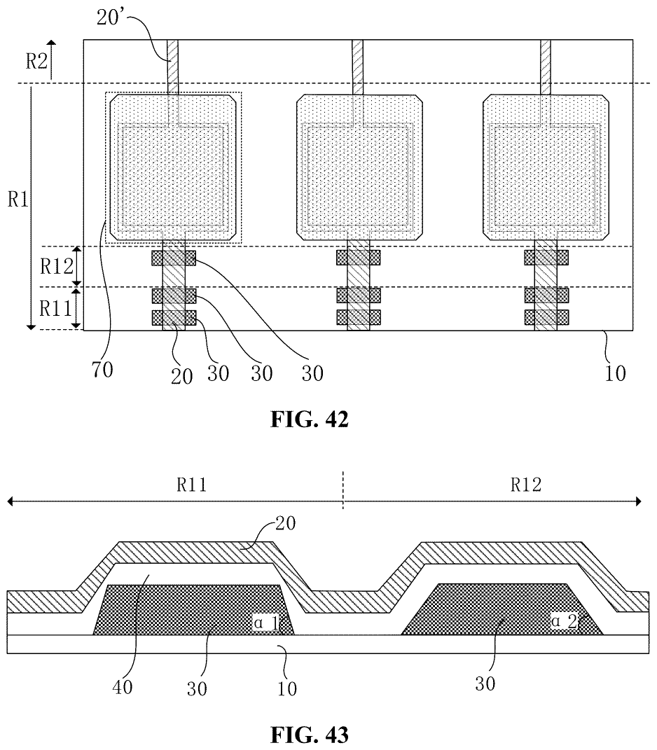

FIG. 42 is a detailed schematic diagram of a partial region shown in FIGS. 1 and 2.

As shown in FIG. 42, the first region R1 of the display substrate 01 may include a first sub-region R11 and a second sub-region R12. The second sub-region R12 is located between the first sub-region R11 and the second region R2. Thus, the first sub-region R11 is closer to the edge of the display substrate 01 than the second sub-region R12. To balance process yield, process difficulty, and electrostatic protection, the conductive pads 30 in the first sub-region R11 and the second sub-region R12 can be arranged differently.

In some embodiments, as shown in FIG. 42, the density of the conductive pads 30 in the first sub-region R11 is greater than that in the second sub-region R12. Among the portions of the lead traces 20 located in the first sub-region R11 and the portions of the lead traces 20 located in the second sub-region R12, the number density of the conductive pads 30 overlapped by the portions located in the first sub-region R11 is greater than the number density of the conductive pads 30 overlapped by the portions located in the second sub-region R12. The number density of the conductive pads 30 overlapped by different portions of the lead traces 20 refers to the number of conductive pads 30 overlapped by different portions of the lead trace 20 per unit length in the direction in which the lead traces 20 extend. For example, as shown in FIG. 42, the first sub-region R11 and the second sub-region R12 are arranged along the column direction, and the lead trace 20 extends along the column direction. If the length of the lead trace 20 extending along the column direction in the first sub-region R11 is substantially the same as the length of the lead trace 20 extending along the column direction in the second sub-region R12, the lead trace 20 overlaps two conductive pads 30 in the first sub-region R11 and overlaps one conductive pad 30 in the second sub-region R12.

In this embodiment, by setting the density of the conductive pads 30 in the first sub-region R11 to be greater than the density of the conductive pads 30 in the second sub-region R12, so that the number of weak points P1 in the first sub-region R11 closer to the edge of the display substrate 01 is greater, which is conducive to the discharge of static electricity in the first region R11. In other words, static electricity is discharged closer to the edge of the display substrate 01, effectively protecting the functional components of the display substrate 01. Especially when the display substrate 01 needs to be grinded, the grinding position is located at the edge of the display substrate 01. Therefore, the static electricity density close to the edge of the display substrate 01 is higher, and this part of static electricity can be effectively discharged by the technical solution of this embodiment.

FIG. 43 is a schematic cross-sectional view of a partial region of a display substrate provided in some embodiments of the present application.

In some embodiments, as shown in FIG. 43, the sidewall inclination angle α1 of the conductive pad 30 in the first sub-region R11 is greater than the sidewall inclination angle α2 of the conductive pad 30 in the second sub-region R12. Consequently, the weak point P1 formed by the overlap of the first insulating layer 40 and lead trace 20 with the conductive pad 30 in the first sub-region R11 is more likely to become a sacrificial point for static discharge than the weak point P1 formed by the overlap of the first insulating layer 40 and lead trace 20 with the conductive pad 30 in the second sub-region R12.

In this embodiment, by setting the sidewall inclination angle α1 of the conductive pad 30 in the first sub-region R11 to be greater than the sidewall inclination angle α2 of the conductive pad 30 in the second sub-region R12, so that the weak point P1 in the first sub-region R11 closer to the edge of the display substrate 01 is more likely to discharge static electricity, which is conducive to the discharge of static electricity in the first region R11, in other words, static electricity is discharged closer to the edge of the display substrate 01, effectively protecting the functional components of the display substrate 01. Especially when the display substrate 01 needs to be grinded, the grinding position is located at the edge of the display substrate 01. Therefore, the static electricity density close to the edge of the display substrate 01 is higher, and this part of static electricity can be effectively discharged by the technical solution of this embodiment.

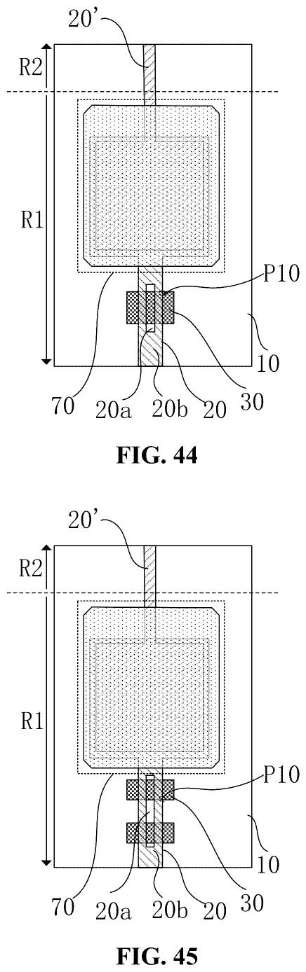

FIG. 44 is a detailed schematic diagram of the partial region shown in FIGS. 1 and 2.

During the simulation experiment of the solution in the present application, the inventors found that in the overlapping region between the lead trace 20 and the conductive pad 30, the probability of static electricity being discharged at a position close to the corner position of the overlapping region is greater than the probability of static electricity being discharged at other positions. The weak point P1 at the position close to the corner position of the overlapping region is called the obvious weak point P10.

To increase the number of significant weak points P10, in one embodiment of the present application, as shown in FIG. 44, the lead trace 20 includes a hollow portion 20a and a solid portion 20b located outside the hollow portion 20a. In a direction perpendicular to the plane where the display substrate 01 is located, the hollow portion 20a and parts of the solid portions 20b located outside the hollow portion 20a overlap the same conductive pad 30. The number of solid portions 20b overlapping the conductive pads 30 in the same lead trace 20 increases, and the number of obvious weak points P10 corresponding to the overlap between the solid portions 20b and the conductive pads 30 increases, thereby enhancing the electrostatic discharge capability of the display substrate 01.

FIG. 45 is a detailed schematic diagram of the partial region shown in FIGS. 1 and 2.

In a technical solution corresponding to this embodiment, as shown in FIG. 45, in a direction perpendicular to the plane where the display substrate 01 is located, the hollow portion 20a overlaps at least two conductive pads 30. The solid portions 20b on the both sides of the hollow portion 20a also overlap at least two conductive pads 30 in a direction perpendicular to the plane where the display substrate 01 is located, thereby increasing the number of obvious weak points P10. Furthermore, in this technical solution, the hollow portion 20a overlaps at least two conductive pads 30, therefore, the manufacturing difficulty of the hollow portion 20a is relatively low.

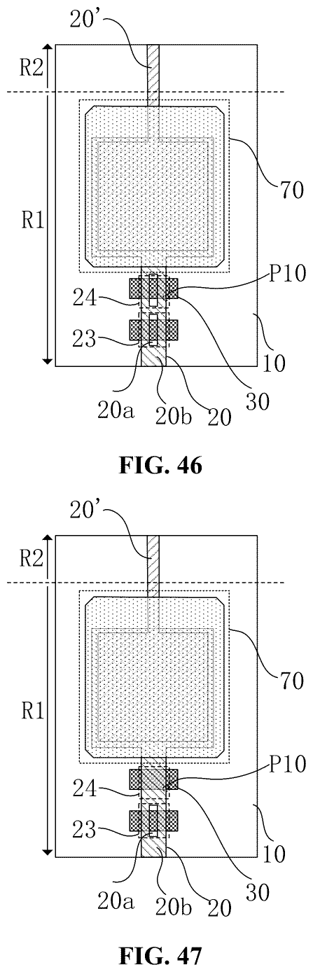

FIG. 46 is a detailed schematic diagram of the partial region shown in FIGS. 1 and 2.

In a technical solution corresponding to this embodiment, as shown in FIG. 46, the lead trace 20 includes a third lead portion 23 and a fourth lead portion 24. The third lead portion 23 is located on the side of the fourth lead portion 24 close to the edge of the display substrate 01. The third lead portion 23 and the fourth lead portion 24 each include a hollow portion 20a. In a direction perpendicular to the plane where the display substrate 01 is located, the hollow portions 20a of the third lead portion 23 and the hollow portions 20a of the fourth lead portion 24 overlap different conductive pads 30 respectively.

In this technical solution, the solid portions 20b of the lead trace 20 located on both sides of the at least two hollow portions 20a overlap the conductive pads 30, thereby significantly reducing the number of weak points P10. Furthermore, the hollow portions 20a that overlap different conductive pads 30 do not penetrate, resulting in relatively low impedance and improved process yield for the lead trace 20.

FIG. 47 is a detailed schematic diagram of a partial region shown in FIGS. 1 and 2.

In a technical solution corresponding to this embodiment, as shown in FIG. 47, the lead trace 20 includes a third lead portion 23 and a fourth lead portion 24. The third lead portion 23 is located on the side of the fourth lead portion 24 close to the edge of the display substrate 01. The third lead portion 23 includes a hollow portion 20a, while the fourth lead portion 24 does not include a hollow portion 20a. In a direction perpendicular to the plane where the display substrate 01 is located, the hollow portion 20a of the third lead portion 23 overlaps the conductive pad 30, and the fourth lead portion 24 overlaps the conductive pad 30.

In this technical solution, the hollow portion 20b is only provided on the third lead portion 23, so that the manufacturing difficulty of the hollow portion 20b is relatively low. Furthermore, the hollow portion 20b of the lead trace 20 is located on the third lead portion 23 closer to the edge of the display substrate 01. Therefore, more obvious weak points P10 are obtained closer to the edge of the display substrate 01, which is conducive to the discharge of static electricity at a position closer to the edge of the display substrate 01, thereby effectively protecting the functional components in the display substrate 01. Especially when the display substrate 01 needs to be grinded, the grinding position is located at the edge of the display substrate 01. Therefore, the static electricity density close to the edge of the display substrate 01 is higher. This part of static electricity can be effectively discharged by the technical solution of this embodiment.

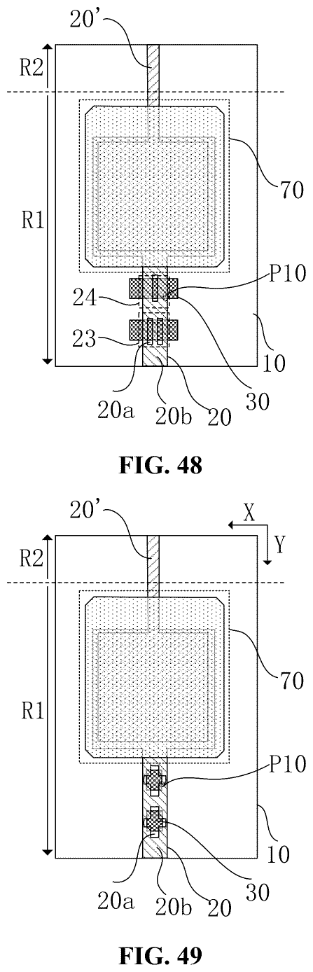

FIG. 48 is a detailed schematic diagram of a partial region shown in FIGS. 1 and 2.

In a technical solution corresponding to this embodiment, as shown in FIG. 48, the lead trace 20 includes a third lead portion 23 and a fourth lead portion 24. The third lead portion 23 is located on the side of the fourth lead portion 24 close to the edge of the display substrate 01. The third lead portion 23 and the fourth lead portion 24 each include a hollow portion 20a. In this technical solution, the number of hollow portions 20a included in the third lead portion 23 is greater than the number of hollow portions 20a included in the fourth lead portion 24. For example, as shown in FIG. 48, the third lead portion 23 includes two hollow portions 20a and the fourth lead portion 24 includes one hollow portion 20a.

In this technical solution, the third lead portion 23 closer to the edge of the display substrate 01 includes more hollow portions 20b, so that more obvious weak points P10 are obtained closer to the edge of the display substrate 01, which is conducive to the discharge of static electricity at a position closer to the edge of the display substrate 01, thereby effectively protecting the functional components in the display substrate 01. Especially when the display substrate 01 needs to be grinded, the grinding position is located at the edge of the display substrate 01. Therefore, the static electricity density close to the edge of the display substrate 01 is higher. This part of static electricity can be effectively discharged by the technical solution of this embodiment. In addition, the fourth lead portion 24 at the edge position farther away from the display substrate 01 also includes a hollow portion 20b. On the one hand, this can allow for more obvious weak points P10 at the position where the lead trace 20 overlaps the conductive pad 30; on the other hand, it can avoid excessive hollow portions 20b on the lead trace 20, which would otherwise lead to a significant increase in the impedance and a decrease in the yield of the lead trace 20.

FIG. 49 is a detailed schematic diagram of a partial region shown in FIGS. 1 and 2.

In a technical solution corresponding to this embodiment, as shown in FIG. 49, in a direction perpendicular to the plane where the display substrate 01 is located, the hollow portion 20a overlaps the edge of the conductive pad 30 extending along the first direction X, and the hollow portion 20a overlaps the edge of the conductive pad 30 extending along the second direction Y. Both the first direction X and the second direction Y are parallel to the plane where the display substrate 01 is located, and the first direction X and the second direction Y intersect. Furthermore, because parts of the solid portions 20b surrounding the hollow portion 20a overlap the same conductive pad 30, the solid portions 20b surrounding the hollow portion 20a that overlap edges extending in different directions of the conductive pad 30 also overlap those edges extending in different directions. Therefore, more obvious weak points P10 can be obtained.

For example, as shown in FIG. 49, when the hollow portion 20a overlaps the edge of the conductive pad 30 extending along the first direction X, and the solid portions 20b surrounding the hollow portion 20a also overlap the edge of the conductive pad 30 extending along the first direction X, the region near the intersection of the edge of the hollow portion 20a and the edge of the conductive pad 30 extending along the first direction X is an obvious weak point P10; and when the hollow portion 20a overlaps the edge of the conductive pad 30 extending along the second direction YY, and the solid portions 20b surrounding the hollow portion 20a also overlap the edges of the conductive pad 30 extending along the second direction YY, the region near the intersection of the edge of the hollow portion 20a and the edge of the conductive pad 30 extending along the second direction YY is also an obvious weak point P10.

In one implementation, as shown in FIG. 49, the hollow portions 20a that overlap the edges of the conductive pad 30 extending in different directions can be a connected structure. For example, the shape of the hollow portions 20a may be a cross.

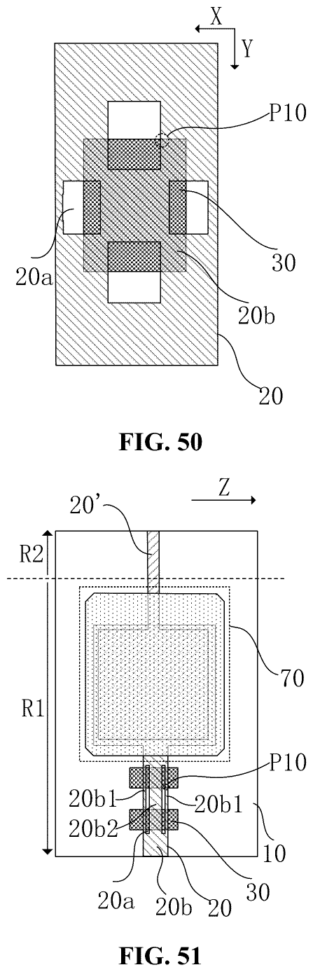

FIG. 50 is a detailed schematic diagram of a partial region shown in FIGS. 1 and 2.

In one implementation, as shown in FIG. 50, the hollow portions 20a that overlap edges of the conductive pads 30 extending in different directions are not connected. For example, in FIG. 50, the left and right hollow portions 20a overlap edges of the conductive pads 30 extending in the second direction Y, and the upper and lower hollow portions 20a overlap edges of the conductive pads 30 extending in the first direction X.

FIG. 51 is an overlap schematic diagram of lead traces and conductive pads in a display substrate provided in some embodiments of the present application.

In a technical solution corresponding to this embodiment, as shown in FIG. 51, the lead trace 20 includes multiple solid portions 20b arranged along a third direction Z. The multiple solid portions 20b each include a first solid portion 20b1 and a second solid portion 20b2. The first solid portions 20b1 are located on both sides of the second solid portion 20b2, and the width of the first solid portion 20b1 along the third direction Z is smaller than the width of the second solid portion 20b2 along the third direction Z.

For example, as shown in FIG. 51, the lead trace 20 includes two hollow portions 20a arranged along the third direction Z. These two hollow portions 20a divide the lead trace 20 into three solid portions 20b arranged along the third direction Z. The outer solid portion 20b are referred to as the first solid portion 20b1, and the inner solid portion 20b is referred to as the second solid portion 20b2. The width of each of the two outer first solid portions 20b1 along the third direction Z is smaller than the width of the inner second solid portion 20b2.

In one implementation, as shown in FIG. 51, the third direction Z can be substantially perpendicular to the extension direction of the lead trace 20.

In this technical solution, the width of the outer solid portion 20b is narrower, so that the static electricity on the lead trace 20 can be discharged more easily at the edge of the lead trace 20; in addition, the width of the inner solid portion 20b is wider. The design of the inner solid portion 20b with a relatively large width reduces the impedance of the lead trace 20 and improves the process yield.

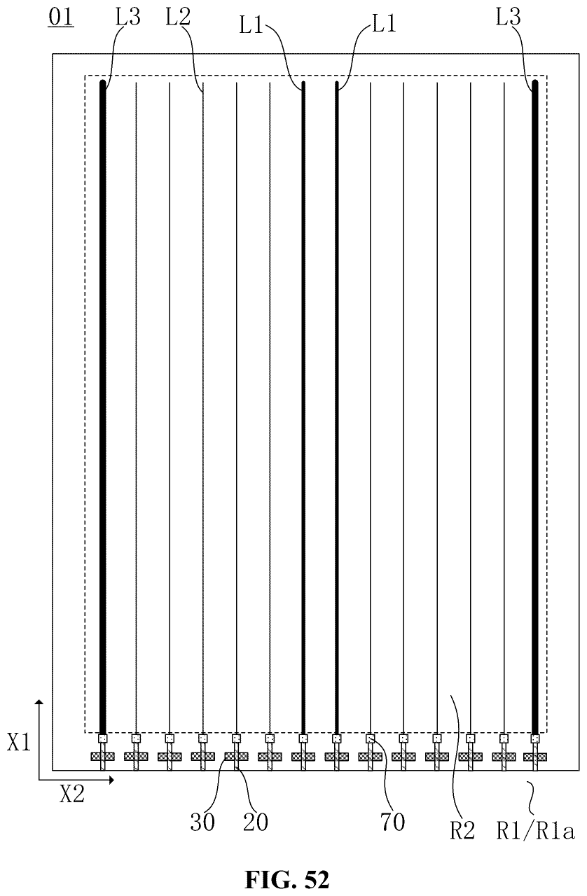

FIG. 52 is a partial schematic diagram of a display substrate provided in some embodiments of the present application.

In one embodiment of the present application, as shown in FIG. 52, the display substrate 01 includes first signal lines L1, second signal lines L2, and third signal lines L2. The first signal lines L1 are configured to transmit pulse signals, the second signal lines L2 are configured to transmit data voltages, and the third signal lines L2 are configured to transmit fixed voltage signals. That is, parts of the functional signal lines 20′ are the first signal lines L1, parts of the functional signal lines 20′ are the second signal lines L2, and parts of the functional signal lines 20′ are the third signal lines L3.

For example, the first signal line L1 transmits a clock signal for a shift register and/or the first signal line L1 transmits a clock signal, etc. for a multiplexer. For example, the second signal line L2 transmits a data voltage for a pixel driver circuit or a data voltage, etc. for a pixel switch transistor. For example, the third signal line L2 transmits a power supply voltage for a shift register and/or the third signal line L2 transmits a power supply voltage, a reset voltage, etc. for a pixel circuit.

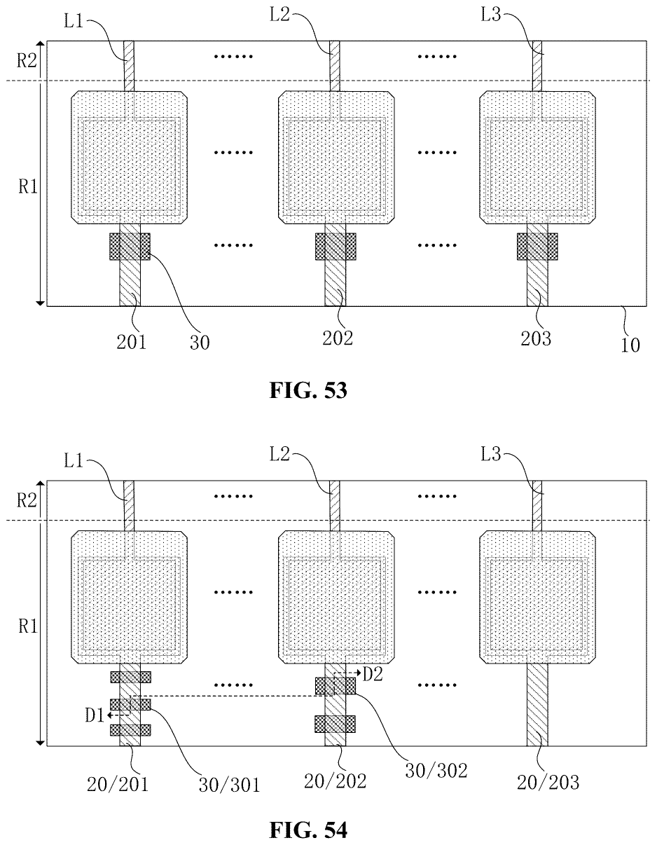

FIG. 53 is a partial schematic diagram of a display substrate provided in some embodiments of the present application.

In conjunction with FIGS. 52 and 53, in order to ensure that the first signal line L1, the second signal line L2, and the third signal line L2 respectively receive the signals transmitted therethrough during the performance test phase of the display substrate 01, parts of the lead traces 20 are the first lead traces 201, parts of the lead traces 20 are the second lead traces 202, and parts of the lead traces 20 are the third lead traces 203. The first lead trace 201 is electrically connected to the first signal line L1, the second lead trace 202 is electrically connected to the second signal line L2, and the third lead trace 203 is electrically connected to the third signal line L2.

In a direction perpendicular to the plane where the display substrate 01 is located, at least one of the first lead trace 201, the second lead trace 202, and the third lead trace 203 overlaps the conductive pad 30. For example, as shown in FIGS. 52 and 53, the first lead trace 201, the second lead trace 202, and the third lead trace 203 each overlap the conductive pad 30 in a direction perpendicular to the plane where the display substrate 01 is located.

The first signal line L1, the second signal line L2, and the third signal line L3 have different requirements for electrostatic protection. For example, the signal types transmitted by the first signal line L1, the second signal line L2 and the third signal line L3 are obviously different. The signals transmitted on these signal lines have different sensitivities to electrostatic interference; the structural differences among the first signal line L1, the second signal line L2, and the third signal line L3 may also lead to different sensitivities to static electricity. Based on the different electrostatic protection requirements of the first signal line L1, the second signal line L2 and the third signal line L3, the number and structure of the weak points P1 corresponding to the first lead trace 201, the second lead trace 202 and the third lead trace 203 can be designed differently.

FIG. 54 is a partial schematic diagram of a display substrate provided in some embodiments of the present application.

In a technical solution corresponding to this embodiment, in a direction perpendicular to the plane where the display substrate 01 is located, the first lead trace 201 and the second lead trace 202 each overlap conductive pads 30. The number of conductive pads 30 overlapped by the first lead trace 201 is greater than the number of conductive pads 30 overlapped by the second lead trace 202. Therefore, the number of conductive pads 30 overlapped by the lead trace 20 transmitting the pulse signal for the first signal line L1 is greater than the number of conductive pads 30 overlapped by the lead trace 20 transmitting the data voltage for the second signal line L2.

For example, as shown in FIG. 53, the first lead trace 201 overlaps three conductive pads 30 in a direction perpendicular to the plane where the display substrate 01 is located, and the second lead trace 202 overlaps two conductive pads 30 in a direction perpendicular to the plane where the display substrate 01 is located.

In this technical solution, the accuracy of the pulse signal has a great influence on the display driving of the display substrate 01. Therefore, the requirements for the signal transmitted on the first signal line L1 are high, and interference from static electricity should be avoided as much as possible. In addition, the risk of the voltage fluctuation of the pulse signal breaking through the insulating layer is relatively high. If static electricity is added, the risk of the first signal line L1 breaking through the insulating layer is further increased. In summary, the first signal line L1 has higher requirements for electrostatic protection. By providing more conductive pads 30 overlapping the first lead trace 201, the stability of the signal transmitted by the first signal line L1 can be effectively guaranteed.

The data voltage is also a variable signal. Although its frequency of variation is lower than that of the pulse signal, it is also more susceptible to static electricity, further affecting the display driving performance of the display substrate 01. Therefore, the second lead trace 202 can also overlap the conductive pad 30 in a direction perpendicular to the plane where the display substrate 01 is located to reduce the impact of static electricity on the signal transmitted by the second signal line L2.

Furthermore, the signal transmitted by the third signal line L3 is less susceptible to static electricity than the signals transmitted by the first signal line L1 and second signal line L2. For example, when the third signal line L3 is configured to transmit the power supply voltage required by the pixel circuit, the third signal line L3 transmitting the power supply voltage is typically electrically connected across its entire surface. That is, the third signal lines L3 at different locations are electrically connected together, and the signals transmitted therethrough are less susceptible to static electricity.

In one implementation, as shown in FIG. 54, the third lead trace 203 does not overlap the conductive pad 30 in a direction perpendicular to the plane where the display substrate 01 is located.

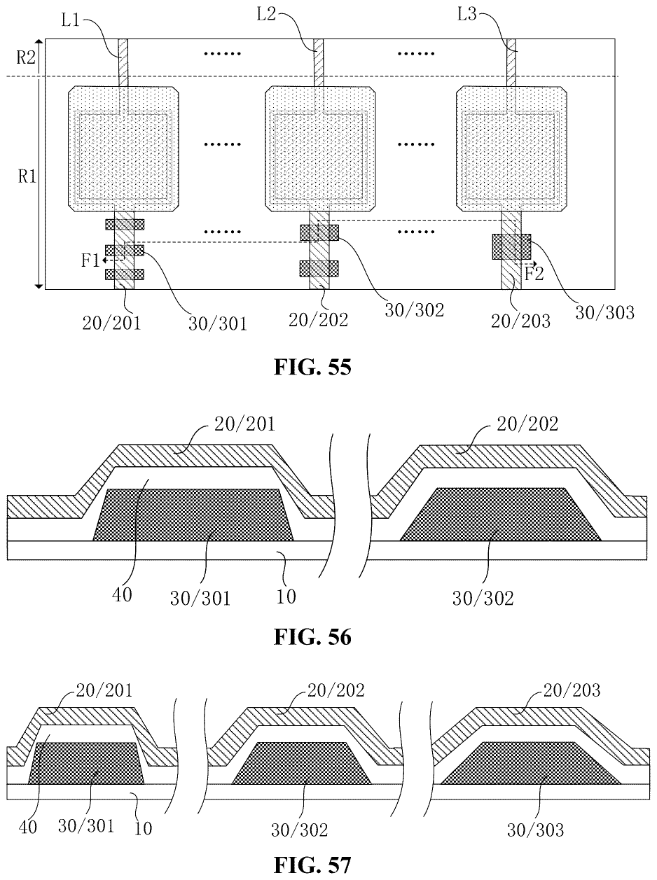

FIG. 55 is a partial schematic diagram of a display substrate provided in some embodiments of the present application.

In one implementation, as shown in FIG. 55, in a direction perpendicular to the plane where the display substrate 01 is located, the third lead trace 203 also overlaps the conductive pad 30, and the number of conductive pads 30 overlapped by the second lead trace 202 is greater than the number of conductive pads 30 overlapped by the third lead trace 203. Therefore, the number of conductive pads 30 overlapped by the third lead trace 203 is less than the number of conductive pads 30 overlapped by the first lead trace 201 and less than the number of conductive pads overlapped by the second lead trace 202.

For example, as shown in FIG. 55, the first lead trace 201 overlaps three conductive pads 30 in a direction perpendicular to the plane where the display substrate 01 is located, the second lead trace 202 overlaps two conductive pads 30 in a direction perpendicular to the plane where the display substrate 01 is located; and the third lead trace 203 overlaps one conductive pad 30 in a direction perpendicular to the plane where the display substrate 01 is located.

In one implementation, as shown in FIGS. 54 and 55, the width of the conductive pad 30 overlapping the first lead trace 201 in the extension direction of the first lead trace 201 is smaller than the width of the conductive pad 30 overlapping the second lead trace 202 in the extension direction of the second lead trace 202. The conductive pad 301 overlapping the first lead trace 201 is the first conductive pad 301, and the conductive pad 302 overlapping the second lead trace 202 is the second conductive pad 302, and the width of the first conductive pad 301 in the extension direction of the lead trace 20 overlapping the first conductive pad 301 is smaller than the width of the second conductive pad 301 in the extension direction of the lead trace 20 overlapping the second conductive pad 301.

For example, as shown in FIGS. 54 and 55, the lead traces 20 all extend along the column direction, and the three first conductive pads 301 overlapping the first lead trace 201 are also arranged along the column direction, and the two second conductive pads 302 overlapping the second lead trace 202 are also arranged along the column direction, wherein the width of the first conductive pad 301 along the column direction is smaller than the width of the second conductive pad 302 along the column direction.

When the number of conductive pads 30 overlapped by the first lead trace 201 is greater than the number of conductive pads 30 overlapped by the second lead trace 202, the width of the first conductive pad 301 overlapped by the first lead trace 201 along its arrangement direction is smaller than the width of the first conductive pad 301 overlapped by the second lead trace 202 along its arrangement direction. Therefore, more conductive pads 30 overlapped by the first lead trace 201 can be arranged in a relatively small space without increasing the number of first lead traces 201, so that the first region R1 has a relatively small width.

Furthermore, as shown in FIG. 55, when the number of conductive pads 30 overlapped by the second lead trace 202 is greater than the number of conductive pads 30 overlapped by the third lead trace 203, the width of the second conductive pad 302 overlapped by the second lead trace 202 along the extension direction of the second lead trace 202 can also be smaller than the width of the third conductive pad 302 overlapped by the third lead trace 203 along the extension direction of the third lead trace 203.

FIG. 56 is a schematic cross-sectional view in a direction of D1-D2 in FIG. 54.

In a technical solution corresponding to this embodiment, as shown in FIG. 56, in a direction perpendicular to the plane where the display substrate 01 is located, the first lead trace 201 and the second lead trace 202 each overlap the conductive pad 30, and the sidewall inclination angle of the conductive pad 30 overlapping the first lead trace 201 is greater than the sidewall inclination angle of the conductive pad 30 overlapping the second lead trace 202. As shown in FIG. 56, the sidewall inclination angle of the first conductive pad 301 is greater than the sidewall inclination angle of the second conductive pad 302.

When the sidewall inclination angle of the first conductive pad 301 is larger, the static electricity on the first lead trace 201 can be more easily discharged. In addition, when the sidewall inclination angle of the second conductive pad 302 is smaller than the sidewall inclination angle of the first conductive pad 301, the risk of trace breakage at the position where the second lead trace 202 overlaps the sidewall of the second conductive pad 302 can be reduced, thereby reducing the probability of a lead trace 20 being broken among all the lead traces 20.

FIG. 57 is a schematic cross-sectional view in a direction of F1-F2 in FIG. 55.

In one implementation, as shown in FIG. 57, in a direction perpendicular to the plane where the display substrate 01 is located, the third lead trace 203 also overlaps the conductive pad 30, and the sidewall inclination angle of the conductive pad 30 overlapping the second lead trace 202 is greater than the sidewall inclination angle of the conductive pad 30 overlapping the third lead trace 203. As shown in FIG. 57, the sidewall inclination angle of the first conductive pad 301 is greater than the sidewall inclination angle of the second conductive pad 302, and the sidewall inclination angle of the second conductive pad 302 is greater than the sidewall inclination angle of the third conductive pad 303.

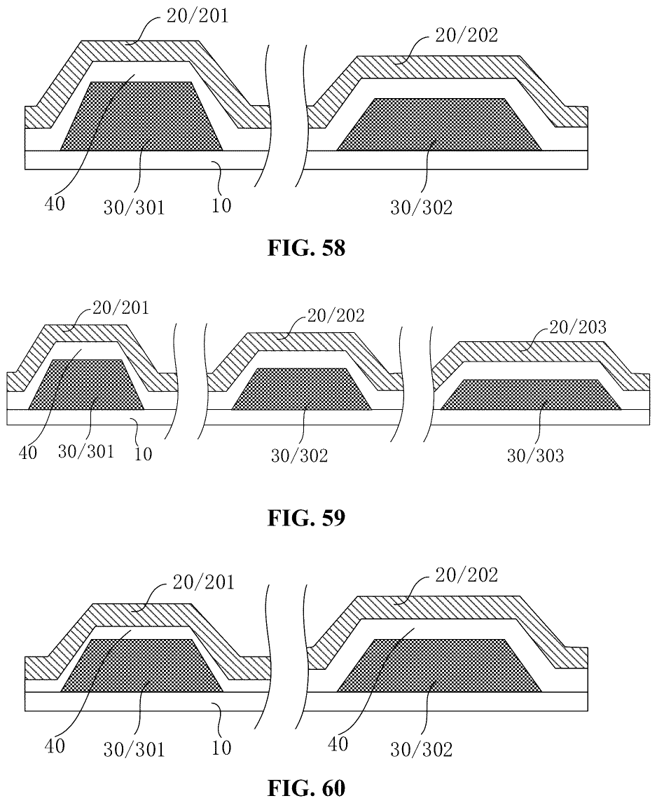

FIG. 58 is another schematic cross-sectional view in a direction of D1-D2 in FIG. 54.

In a technical solution corresponding to this embodiment, as shown in FIG. 58, in a direction perpendicular to the plane where the display substrate 01 is located, the first lead trace 201 and the second lead trace 202 each overlap the conductive pad 30, and the height of the conductive pad 30 overlapping the first lead trace 201 is greater than the height of the conductive pad 30 overlapping the second lead trace 202. As shown in FIG. 58, the height of the first conductive pad 301 is greater than the height of the second conductive pad 302.

When the height of the first conductive pad 301 is greater, static electricity on the first lead trace 201 can be more easily discharged. In addition, when the height of the second conductive pad 302 is smaller than that of the first conductive pad 301, the risk of trace breakage at the position where the second lead trace 202 overlaps the sidewall of the second conductive pad 302 can be reduced, thereby reducing the probability of a lead trace 20 being broken among all the lead traces 20.

FIG. 59 is another schematic cross-sectional view in a direction of F1-F2 in FIG. 55.

In one implementation, as shown in FIG. 59, in a direction perpendicular to the plane where the display substrate 01 is located, the third lead trace 203 also overlaps the conductive pad 30, and the height of the conductive pad 30 overlapping the second lead trace 202 is greater than the height of the conductive pad 30 overlapping the third lead trace 203. As shown in FIG. 59, the height of the first conductive pad 301 is greater than the height of the second conductive pad 302, and the sidewall inclination angle of the second conductive pad 302 is greater than the sidewall inclination angle of the third conductive pad 303.

FIG. 60 is another schematic cross-sectional view in a direction of D1-D2 in FIG. 54.

In a technical solution corresponding to this embodiment, as shown in FIG. 60, in a direction perpendicular to the plane where the display substrate 01 is located, the first lead trace 201 and the second lead trace 202 each overlap the conductive pad 30, and the thickness of the insulating layer between the first lead trace 201 and the overlapping conductive pad 30 is less than the thickness of the insulating layer between the second lead trace 202 and the overlapping conductive pad 30. As shown in FIG. 60, the thickness of the first insulating layer 40 between the first lead trace 201 and the first conductive pad 301 is smaller than the thickness of the first insulating layer 40 between the second lead trace 202 and the second conductive pad 302.

When the thickness of the insulating layer 40 between the first lead trace 201 and the first conductive pad 301 is smaller, static electricity on the first lead trace 201 can be more easily discharged.

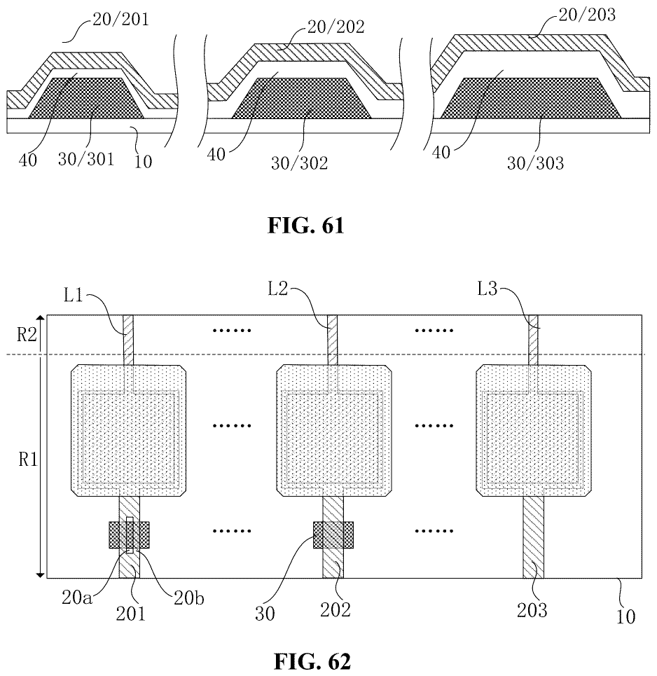

FIG. 61 is another schematic cross-sectional view in a direction of F1-F2 in FIG. 55.

In one implementation, as shown in FIG. 61, in a direction perpendicular to the plane where the display substrate 01 is located, the third lead trace 203 also overlaps the conductive pad 30, and the thickness of the insulating layer between the second lead trace 202 and the overlapping conductive pad 30 is smaller than the thickness of the insulating layer between the third lead trace 203 and the overlapping conductive pad 30. As shown in FIG. 59 , the thickness of the first insulating layer 40 between the first lead trace 201 and the first conductive pad 301 is smaller than the thickness of the first insulating layer 40 between the second lead trace 202 and the second conductive pad 302, and the thickness of the first insulating layer 40 between the second lead trace 202 and the second conductive pad 302 is smaller than the thickness of the first insulating layer 40 between the third lead trace 203 and the third conductive pad 303.

FIG. 62 is a partial schematic diagram of a display substrate provided in some embodiments of the present application.

In a technical solution corresponding to this embodiment, as shown in FIG. 62, a first lead trace 201 includes a hollow portion 20a and a solid portion 20b located outside the hollow portion 20a. In a direction perpendicular to the plane where the display substrate 01 is located, the hollow portion 20a and parts of the solid portions 20b located outside the hollow portion 20a overlap the same conductive pad 30. This technical solution can improve the static discharge efficiency of the first lead trace 201.

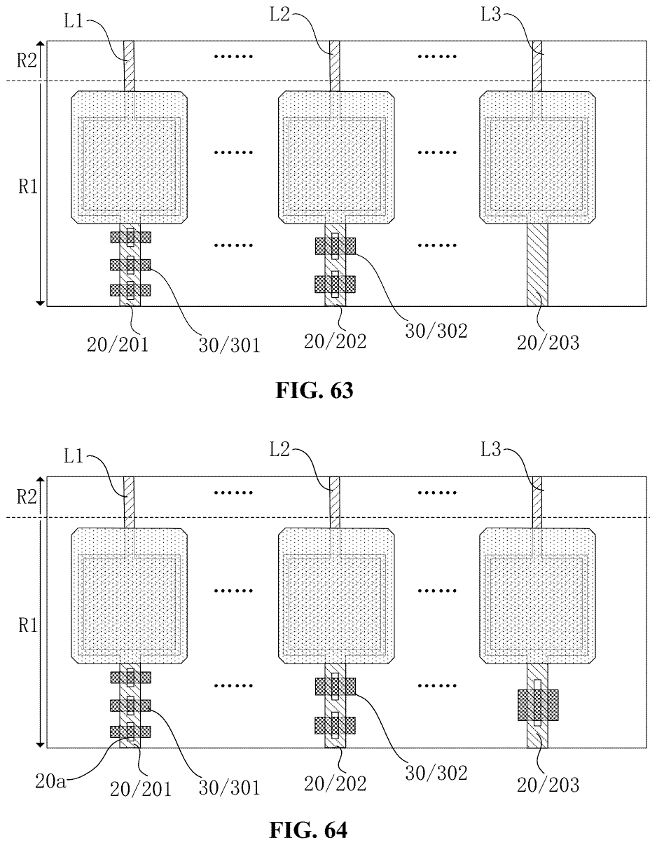

FIG. 63 is a partial schematic diagram of a display substrate provided in some embodiments of the present application.

In one implementation, as shown in FIG. 63, a second lead trace 202 includes a hollow portion 20a and a solid portion 20b located outside the hollow portion 20a. The number of hollow portions 20a included in the first lead trace 201 is greater than the number of hollow portions 20a included in the second lead trace 202. As shown in FIG. 63, the first lead trace 201 includes three hollow portions 20a, and the second lead trace 202 includes two hollow portions 20a.

When the first lead trace 201 has more hollow portions 20a, static electricity on the first lead trace 201 can be more easily discharged. Furthermore, when the number of hollow portions 20a on the first lead trace 201 is greater than the number of hollow portions 20a on the second lead trace 202, the risk of the second lead trace 202 being broken due to too many hollow portions 20 a can be reduced, thereby reducing the probability of the lead trace 20 being broken among all the lead traces 20.

In one implementation, as shown in FIG. 62, the second lead trace 202 may also not include any hollow portion 20a.

FIG. 64 is a partial schematic diagram of a display substrate provided in some embodiments of the present application.

Optionally, as shown in FIG. 64, the third lead trace 203 includes a hollow portion 20a and a solid portion 20b located outside the hollow portion 20a. The number of hollow portions 20a included in the second lead trace 202 is greater than the number of hollow portions 20a included in the third lead trace 203. As shown in FIG. 64, the first lead trace 201 includes three hollow portions 20a, the second lead trace 202 includes two hollow portions 20a, and the third lead trace 203 includes one hollow portion 20a.

Optionally, the third lead trace 203 may not include any hollow portion 20a.

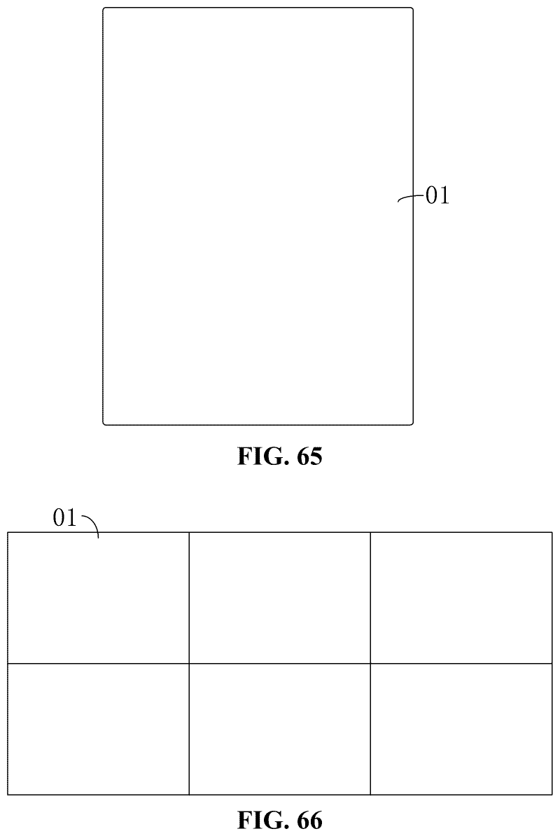

FIG. 65 is a schematic diagram of a display apparatus provided in some embodiments of the present application, and FIG. 66 is a schematic diagram of a display apparatus provided in some embodiments of the present application.

Based on the same inventive concept, some embodiments of the present invention further provide a display apparatus, as shown in FIG. 65, which includes the aforementioned display substrate 01. The display apparatus shown in FIG. 65 is merely illustrative. The display apparatus may be any electronic device with a display function, such as a mobile phone, tablet computer, laptop computer, e-reader, or television.

Based on the same inventive concept, some embodiments of the present invention further provides a spliced display apparatus, as shown in FIG. 66. This display apparatus is a spliced display apparatus that includes the aforementioned display substrate 01. At least a part of the first region R1 of the display substrate 01 can serve as its splicing side, which is the side of the display substrate 01 that splices with adjacent display substrates 01. This type of spliced display apparatus can be a splicing large screen and can be used in public information display (PID) scenarios such as stations and airports. When a spliced display apparatus includes the aforementioned display substrate 01, the antistatic ability of the apparatus can be effectively improved, thereby improving the display effect of the spliced display apparatus.

The above description is only a preferred embodiment of the present application and is not intended to limit the present application. Any modifications, equivalent replacements, improvements, etc. made within the gist and principles of the present application shall be included in the scope of protection in the present application.

What is claimed is:

1. A display substrate, comprising a first region and a second region, the first region being located at a side of the second region close to an edge of the display substrate, the second region comprising a plurality of first transistors, at least one of the first transistors being electrically connected to a first electrode, the display substrate comprising:
a substrate;
lead traces located in the first region;
conductive pads located between a film layer where the lead traces are located and the substrate, wherein in a direction perpendicular to a plane where the display substrate is located, at least one of the conductive pads overlaps a corresponding one of the lead traces;
a first insulating layer located between a film layer where the conductive pads are located and the film layer where the lead traces are located, the first insulating layer being comprised between the conductive pads and the lead traces.

2. The display substrate according to claim 1, wherein the display substrate comprises a first film layer, the first film layer comprising a first structure in the second region,
at least one of the conductive pads comprises a first portion, the first portion is located in the first film layer, and in the direction perpendicular to the plane where the display substrate is located, a thickness of the first portion is greater than a thickness of the first structure; or
the display substrate comprises a first film layer, the first film layer comprises a first structure in the second region,
at least one of the conductive pads comprises a first portion, the first portion is located in the first film layer, and
a sidewall inclination angle of the first portion is greater than a sidewall inclination angle of the first structure.

3. The display substrate according to claim 1, wherein the display substrate further comprises a second insulating layer, the second insulating layer is located between different conductive film layers, and
in the direction perpendicular to the plane where the display substrate is located, a thickness of the first insulating layer is less than a thickness of the second insulating layer; or
a thickness of a portion of the first insulating layer located between the conductive pads and the lead traces is smaller than a thickness of a portion of the first insulating layer located in the second region.

4. The display substrate according to claim 1, further comprising:
transfer electrode blocks located in the first region, wherein at least one of the transfer electrode blocks comprises at least two transfer electrodes arranged in the direction perpendicular to the plane where the display substrate is located and located in different conductive film layers, at least one of the transfer electrode blocks comprises a first transfer electrode, and the first transfer electrode is located at a side of the other transfer electrodes away from the substrate,
at least one of the lead traces is electrically connected to a corresponding one of the transfer electrode blocks, and at least a portion of the lead trace and the first transfer electrode are located in a same film layer.

5. The display substrate according to claim 4, wherein the transfer electrode block further comprises a second transfer electrode and a third transfer electrode, the second transfer electrode and the third transfer electrode are located at a side of the first transfer electrode close to the substrate;
at least one of the conductive pads comprises a portion located in a same film layer as the second transfer electrode and a portion located in a same film layer as the third transfer electrode.

6. The display substrate according to claim 4, wherein at least one of the lead traces comprises a first lead portion and a second lead portion, the first lead portion is reused as the first transfer electrode, and in the direction perpendicular to the plane where the display substrate is located, the second lead portion does not overlap a corresponding one of the transfer electrode blocks;
for at least one of at least part of the lead traces, the first lead portion overlaps a corresponding one of the conductive pads in the direction perpendicular to the plane where the display substrate is located.

7. The display substrate according to claim 1, wherein the first transistor comprises a semiconductor layer and a gate, and the first insulating layer is between the semiconductor layer and the gate,
at least a portion of the conductive pads is located in a same film layer as the semiconductor layer, and at least a portion of the lead traces is located in a same film layer as the gate; or
the display substrate further comprises a capacitor, the first transistor comprises a gate, the capacitor comprises a first electrode plate and a second electrode plate, the first electrode plate and the gate are located in a same film layer,
at least a portion of the conductive pads is located in a same film layer as the first electrode plate, and at least a portion of the lead traces is located in a same film layer as the second electrode plate.

8. The display substrate according to claim 1, wherein at least one of the lead traces overlaps at least two of the conductive pads in the direction perpendicular to the plane where the display substrate is located.

9. The display substrate according to claim 8, wherein at least two adjacent conductive pads of the conductive pads overlapping a same one of the lead traces are connected to each other.

10. The display substrate according to claim 8, wherein the first region comprises a first sub-region and a second sub-region, and the second sub-region is located between the first sub-region and the second region, and
a sidewall inclination angle of at least one of the conductive pads in the first sub-region is greater than a sidewall inclination angle of at least one of the conductive pads in the second sub-region; or
the first region comprises a first sub-region and a second sub-region, the second sub-region is located between the first sub-region and the second region, and
a density of the conductive pads in the first sub-region is greater than a density of the conductive pads in the second sub-region.

11. The display substrate according to claim 1, wherein at least one of the conductive pads comprises a first surface in contact with the first insulating layer, a shape of the first surface comprising at least one vertex angle;
in the direction perpendicular to the plane where the display substrate is located, at least one of the lead traces overlaps at least one of the at least one vertex angles.

12. The display substrate according to claim 1, wherein at least one of the lead traces comprises a third lead portion and a fourth lead portion, the third lead portion is located at a side of the fourth lead portion close to an edge of the display substrate;
in a direction perpendicular to an extension direction of the lead trace, a width of the third lead portion is smaller than a width of the fourth lead portion.

13. The display substrate according to claim 1, wherein at least one of the lead traces comprises a hollow portion and a solid portion located around the hollow portion;
in the direction perpendicular to the plane where the display substrate is located, the hollow portion and part of the solid portion located around the hollow portion overlap a same one of the conductive pads.

14. The display substrate according to claim 13, wherein at least one of the lead traces comprises a third lead portion and a fourth lead portion, the third lead portion is located at a side of the fourth lead portion close to the edge of the display substrate, the third lead portion comprises the hollow portion, and the fourth lead portion does not comprise the hollow portion;
in the direction perpendicular to the plane where the display substrate is located, the hollow portion comprised in the third lead portion overlaps a corresponding one of the conductive pads, and the fourth lead portion overlaps a corresponding one of the conductive pads.

15. The display substrate according to claim 13, wherein at least one of the lead traces comprises a third lead portion and a fourth lead portion, the third lead portion is located at a side of the fourth lead portion close to the edge of the display substrate, the third lead portion and the fourth lead portion each comprise the hollow portion, and
in the direction perpendicular to the plane where the display substrate is located, the hollow portion comprised in the third lead portion and the hollow portion comprised in the fourth lead portion overlap different conductive pads of the conductive pads, respectively; or
at least one of the lead traces comprises a third lead portion and a fourth lead portion, the third lead portion is located at a side of the fourth lead portion close to the edge of the display substrate, the third lead portion and the fourth lead portion each comprise the hollow portion, and
a number of the hollow portion comprised in the third lead portion is greater than a number of the hollow portion comprised in the fourth lead portion.

16. The display substrate according to claim 13, wherein in the direction perpendicular to the plane where the display substrate is located, the hollow portion overlaps an edge of a corresponding one of the conductive pads extending in a first direction, and the hollow portion overlaps an edge of a corresponding one of the conductive pads extending in a second direction; the first direction and the second direction are both parallel to the plane where the display substrate is located, and the first direction intersects the second direction.

17. The display substrate according to claim 13, wherein at least one of the lead traces comprises a plurality of solid portions arranged along a third direction; the plurality of solid portions comprise a first solid portion and a second solid portion, the first solid portions are located on both sides of the second solid portion, and a width of the first solid portion along the third direction is smaller than a width of the second solid portion along the third direction.

18. The display substrate according to claim 1, wherein the display substrate comprises a first signal line, a second signal line, and a third signal line, the first signal line is configured to transmit a pulse signal, the second signal line is configured to transmit a data voltage, and the third signal line is configured to transmit a fixed voltage signal;
at least one of the lead traces is a first lead trace, at least one of the lead traces is a second lead trace, and at least one of the lead traces is a third lead trace, the first lead trace is electrically connected to the first signal line, the second lead trace is electrically connected to the second signal line, and the third lead trace is electrically connected to the third signal line;
in the direction perpendicular to the plane where the display substrate is located, at least one of the first lead trace, the second lead trace, and the third lead trace overlaps at least one of the conductive pads.

19. The display substrate according to claim 18, wherein in the direction perpendicular to the plane where the display substrate is located, the first lead trace and the second lead trace each overlap at least one of the conductive pads, and
a number of the at least one conductive pad overlapped by the first lead trace is greater than a number of the at least one conductive pad overlapped by the second lead trace; or
in the direction perpendicular to the plane where the display substrate is located, the first lead trace and the second lead trace each overlap at least one of the conductive pads, and
a sidewall inclination angle of the at least one conductive pad overlapping the first lead trace is greater than a sidewall inclination angle of the at least one conductive pad overlapping the second lead trace; or
in the direction perpendicular to the plane where the display substrate is located, the first lead trace and the second lead trace each overlap at least one of the conductive pads, and
a height of the at least one conductive pad overlapping the first lead trace is greater than a height of the at least one conductive pad overlapping the second lead trace; or
in the direction perpendicular to the plane where the display substrate is located, the first lead trace and the second lead trace each overlap at least one of the conductive pads, and
a thickness of an insulating layer between the first lead trace and the at least one conductive pad overlapping the first lead trace is smaller than a thickness of an insulating layer between the second lead trace and the at least one conductive pad overlapping the second lead trace; or
the first lead trace comprises a hollow portion and a solid portion located around the hollow portion, and in the direction perpendicular to the plane where the display substrate is located, the hollow portion and parts of the solid portions located around the hollow portion overlap a same one of the conductive pads.

20. A display apparatus, comprising a display substrate comprising
a first region and a second region, the first region being located at a side of the second region close to an edge of the display substrate, the second region comprising a plurality of first transistors, at least one of the first transistors being electrically connected to a first electrode, the display substrate comprising:
a substrate;
lead traces located in the first region;
conductive pads located between a film layer where the lead traces are located and the substrate, wherein in a direction perpendicular to a plane where the display substrate is located, at least one of the conductive pads overlaps a corresponding one of the lead traces;
a first insulating layer located between a film layer where the conductive pads are located and the film layer where the lead traces are located, the first insulating layer being comprised between the conductive pads and the lead traces.
